(19) United States
(12) Patent Application Publication
(10) Pub. No.: US 2010/0307586 A1
(43) Pub. Date: Dec. 9, 2010

(54) REFLECTIVE FREE-FORM KOHLER CONCENTRATOR

(75) Inventors: Pablo Benítez, Madrid (ES); Juan Carlos Miñano, Madrid (ES); Maikel Hernandez, Madrid (ES); Marina Buljan, Madrid (ES)

Correspondence Address: DRINKER BIDDLE & REATH;ATTN: INTELLECTUAL PROPERTY GROUP, ONE LOGAN SQUARE, SUITE 2000, PHILADELPHIA, PA, 19103-6996, US

(73) Assignee: Light Prescriptions Innovators, LLC, Altadena, CA (US)

(21) Appl. No.: 12/795,912

(22) Filed: Jun. 8, 2010

Related U.S. Application Data
(60) Provisional application No. 61/268,129, filed on Jun. 8, 2009.

(51) Int. Cl. H01L 31/0232

(52) U.S. Cl. 136/259

(57) ABSTRACT

One example of a solar photovoltaic concentrator has a primary mirror with multiple free-form panels, each of which forms a Köhler integrator with a respective panel of a lenticular secondary lens. The Köhler integrators are folded by a common intermediate mirror. The resulting plurality of integrators all concentrate sunlight onto a common photovoltaic cell. Luminaires using a similar geometry are also described.

### CROSS REFERENCE TO RELATED APPLICATION

This application claims benefit of U.S. Provisional Application No. 61/268,129 titled “Kohler Concentrator”, filed Jun. 8, 2009 in the names of Miñano et al., which is incorporated herein by reference in its entirety.

Reference is made to commonly-assigned International Patent Applications Nos. WO 2007/016363 to Miñano et al. and WO 2007/103994 to Benítez et al. which are incorporated herein by reference in their entirety.

Embodiments of the devices described and shown in this application may be within the scope of one or more of the following U.S. patents and patent applications and/or equivalents in other countries: U.S. Pat. Nos. 6,639,733, issued Oct. 28, 2003 in the names of Miñano et al., 6,896,381, issued May 24, 2005 in the names of Benítez et al., 7,152,985 issued Dec. 26, 2006 in the names of Benítez et al., and 7,460,985 issued Dec. 2, 2008 in the names of Benítez et al.; WO 2007/016363 titled “Free-Form Lenticular Optical Elements and Their Application to Condensers and Headlamps” to Miñano et al and US 2008/0316761 of the same title published Dec. 25, 2008 also in the names of Miñano et al; WO 2007/103994 titled “Multi-Junction Solar Cells with a Homogenizer System and Coupled Non-Imaging Light Concentrator” published Sep. 13, 2007 in the names of Benítez et al; US 2008/0223443, titled “Optical Concentrator Especially for Solar Photovoltaic” published Sep. 18, 2008 in the names of Benítez et al.; and US 2009/0071467 titled “Multi-Junction Solar Cells with a Homogenizer System and Coupled Non-Imaging Light Concentrator” published Mar. 19, 2009 in the names of Benítez et al.

### GLOSSARY

Concentration-Acceptance Product (CAP)—A parameter associated with any solar concentrating architecture, it is the product of the square root of the concentration ratio times the sine of the acceptance angle. Some optical architectures have a higher CAP than others, enabling higher concentration and/or acceptance angle. For a specific architecture, the CAP is nearly constant when the geometrical concentration is changed, so that increasing the value of one parameter lowers the other.

Fresnel Facet—Element of a discontinuous-slope concentrator lens that deflects light by refraction.

TIR Facet—Element of a discontinuous-slope concentrator lens that deflects light by total internal reflection.

Primary Optical Element (POE)—Optical element that receives the light from the sun or other source and concentrates it towards the Intermediate Optical Element, if any, or to the Secondary Optical Element.

Intermediate Optical Element (JOE)—Optical element that receives the light from the Primary Optical Element and concentrates it towards the Secondary Optical Element.

Secondary Optical Element (SOE)—Optical element that receives the light from the Primary Optical Element or from the Intermediate Optical element, if any, and concentrates it towards the solar cell or other target.

Cartesian Oval—A curve (strictly a family of curves) used in imaging and non-imaging optics to transform a given bundle of rays into another predetermined bundle, if there is no more than one ray crossing each point of the surface generated from the curve. The so-called Generalized Cartesian Oval can be used to transform a non-spherical wavefront into another. See Reference [10], page 185, Reference [16].

### BACKGROUND

Triple-junction photovoltaic solar cells are expensive, making it desirable to operate them with as much concentration of sunlight as practical. The efficiency of currently available multi-junction photovoltaic cells suffers when local concentration of incident radiation surpasses ˜2,000-3,000 suns. Some concentrator designs of the prior art have so much non-uniformity of the flux distribution on the cell that “hot spots” up to 9,000-11,000× concentration happen with 500× average concentration, greatly limiting how high the average concentration can economically be. Kaleidoscopic integrators can reduce the magnitude of such hot spots, but they are more difficult to assemble, and are not suitable for small cells.

There are two main design problems in Nonimaging Optics, and both are relevant here. The first is called “bundle-coupling” and its objective is to maximize the proportion of rays in a given input bundle that are transformed into a given output bundle. In a solar concentrator, that is effectively to maximize the proportion of the light power emitted by the sun or other source that is delivered to the receiver. The second problem, known as “prescribed irradiance,” has as its objective to produce a particular illuminance pattern on a specified target surface using a given source emission.

In bundle-coupling, the design problem consists in coupling two ray bundles Mᵢ and Mₒ, called the input and the output bundles respectively. Ideally, this means that any ray entering into the optical system as a ray of the input bundle Mᵢ exits it as a ray of the output bundle Mₒ, and vice versa. Thus the successfully coupled parts of these two bundles Mᵢ and Mₒ comprise the same rays, and thus are the same bundle M_{c}. This bundle M_{c} is in general M_{c}=Mᵢ∩Mₒ. In practice, coupling is always imperfect, so that M_{c}⊂Mᵢ and M_{c}⊂Mₒ.

In prescribed-irradiance, however, it is only specified that one bundle must be included in the other, Mᵢ in Mₒ. Any rays of Mᵢ that are not included in Mₒ are for this problem disregarded, so that Mᵢ is effectively replaced by M_{c}. In this type of solution an additional constraint is imposed that the bundle M_{c} should produce a prescribed irradiance on a target surface. Since M_{c} is not fully specified, this design problem is less restrictive than the bundle coupling one, since rays that are inconvenient to a particular design can be deliberately excluded in order to improve the handling of the remaining rays. For example, the periphery of a source may be under-luminous, so that the rays it emits are weaker than average. If the design edge rays are selected inside the periphery, so that the weak peripheral region is omitted, and only the strong rays of the majority of the source area are used, overall performance can be improved.

Efficient photovoltaic concentrator (CPV) design well exemplifies a design problem comprising both the bundle coupling problem and the prescribed irradiance problem. Mᵢ comprises all rays from the sun that enter the first optical component of the system. Mₒ comprises those rays from the last optical component that fall onto the actual photovoltaic cell (not just the exterior of its cover glass). Rays that are included in Mᵢ but are not coupled into Mₒ are lost, along with their power. (Note that in computer ray tracing, rays from a less luminous part of the source will have less flux, if there are a constant number of rays per unit source area.) The irradiance distribution of incoming sunlight must be matched to the prescribed (usually uniform) irradiance on the actual photovoltaic cell, to preclude hot-spots. Optimizing both problems, i.e., to obtain maximum concentration-acceptance product as well a uniform irradiance distribution on the solar cell's active surface, will maximize efficiency. Of course this is a very difficult task and therefore only partial solutions have been found.

Good irradiance uniformity on the solar cell can be potentially obtained using a light-pipe homogenizer, which is a well known method in classical optics. See Reference [1]. When a light-pipe homogenizer is used, the solar cell is glued to one end of the light-pipe and the light reaches the cell after some bounces on the light-pipe walls. The light distribution on the cell becomes more uniform with light-pipe length. The use of light-pipes for concentrating photo-voltaic (CPV) devices, however, has some drawbacks. A first drawback is that in the case of high illumination angles the reflecting surfaces of the light-pipe must be metalized, which reduces optical efficiency relative to the near-perfect reflectivity of total internal reflection by a polished surface. A second drawback is that for good homogenization a relatively long light-pipe is necessary, but increasing the length of the light-pipe both increases its absorption and reduces the mechanical stability of the apparatus. A third drawback is that light pipes are unsuitable for relatively thick (small) cells because of lateral light spillage from the edges of the bond holding the cell to the end of the light pipe, typically silicone rubber. Light-pipes have nevertheless been proposed several times in CPV systems, see References [2], [3], [4], [5], [6], and [7], which use a light-pipe length much longer than the cell size, typically 4-5 times.

Another strategy for achieving good uniformity on the cell is the Köhler illuminator. Köhler integration can solve, or at least mitigate, uniformity issues without compromising the acceptance angle and without increasing the difficulty of assembly.

Referring to FIG. 2, the first photovoltaic concentrator using Kohler integration was proposed (see Reference [8]) by Sandia Labs in the late 1980's, and subsequently was commercialized by Alpha Solarco. A Fresnel lens 21 was its primary optical element (POE) and an imaging single surface lens 22 (called SILO, for SIngLe Optical surface) that encapsulates the photovoltaic cell 20 was its secondary optical element (SOE). That approach utilizes two imaging optical lenses (the Fresnel lens and the SILO) where the SILO is placed at the focal plane of the Fresnel lens and the SILO images the Fresnel lens (which is uniformly illuminated) onto the photovoltaic cell. Thus, if the cell is square the primary can be square trimmed without losing optical efficiency. That is highly attractive for doing a lossless tessellation of multiple primaries in a module. On the other hand, the primary optical element images the sun onto the secondary surface. That means that the sun image 25 will be formed at the center of the SILO for normal incidence rays 24, and move towards position 25 on the secondary surface as the sun rays 26 move within the acceptance angle of the concentrator due to tracking perturbations and errors. Thus the concentrator's acceptance is determined by the size and shape of the secondary optical element.

Despite the simplicity and high uniformity of illumination on the cell, the practical application of the Sandia system is limited to low concentrations because it has a low concentration-acceptance product of approximately 0.3 (±1° at 300×). The low acceptance angle even at a concentration ratio of 300× is because the imaging secondary cannot achieve high illumination angles on the cell, precluding maximum concentration.

Another previously proposed approach uses four optical surfaces, to obtain a photovoltaic concentrator for high acceptance angle and relatively uniform irradiance distribution on the solar cell (see Reference [9]). The primary optical element (POE) of this concentrator should be an element, for example a double aspheric imaging lens, that images the sun onto the aperture of a secondary optical element (SOE). Suitable for a secondary optical element is the SMS (Simultaneous Multiple Surface) designed RX concentrator described in References [10], [11], [12]. This is an imaging element that works near the thermodynamic limit of concentration. In this notation, the surfaces of the optical device are listed in the order in which the light beam encounters them: I denotes a totally internally reflective surface, R denotes a refractive surface, and X denotes a reflective surface that may be opaque. If a light beam encounters the same surface twice, it is listed at both encounters with the correct type for each encounter.

A good strategy for increasing the optical efficiency of the system (which is a critical merit function) is to integrate multiple functions in fewer surfaces of the system, by designing the concentrator optical surfaces to have at least a dual function, e.g., to illuminate the cell with wide angles, at some specified approximation to uniformity. That entails a reduction of the degrees of freedom in the design compared to the ideal four-surface case. Consequently, there is a trade-off between the selected geometry and the homogenization method, in seeking a favorable mix of optical efficiency, acceptance angle, and cell-irradiance uniformity.

There are two ways to achieve irradiance homogenization. The first is a Köhler integrator, as mentioned before, where the integration process is along both dimensions of the ray bundle, meridional and sagittal. This approach is also known as a 2D Köhler integrator. The other strategy is to integrate in only one of the ray bundle's dimensions; thus called a 1D Köhler integrator. These integrators will typically provide a lesser homogeneity than is achievable with in 2D, but they are easier to design and manufacture, which makes them suitable for systems where uniformity is not too critical. A design method for calculating fully free-form 1D and 2D Köhler integrators was recently developed (see References [13], [14]), where optical surfaces are used that have the dual function of homogenizing the light and coupling the design's edge rays bundles.

In all the embodiments of the present invention, the primary optical element is reflective. The use of reflective primaries is old in solar concentrators, since the parabolic mirror has been in the public domain since centuries. More recently, advanced high-performance free-form asymmetric mirror designs that use a free-form lens with a short kaleidoscope homogenizer protruding from it [14]. designs have been developed. Also recently, the use of two-mirror Cassegrain type concentrators, common in antenna and telescope design, has been extended to solar concentrators with the addition of a kaleidoscope homogenizer [6], and with radial Kohler integration [14] [15].

### SUMMARY

Embodiments of the present invention provide different photovoltaic concentrators that combine high geometric concentration, high acceptance angle, and high irradiance uniformity on the solar cell. In all the embodiments, the primary optical element is reflective in the sense that the light rays exit the primary on the same side that the light rays impinged from. Also in all the embodiments, the primary and secondary optical elements are each lenticulated to form a plurality of segments. In some embodiments, an intermediate optical element, not necessarily segmented, is used in between the primary and the secondary. A segment of the primary optical element and a segment of the secondary optical element combine to form a Köhler integrator. The multiple segments result in a plurality of Köhler integrators that collectively focus their incident sunlight onto a common target, such as a photovoltaic cell. Any hotspots are typically in different places for different individual Köhler integrators, with the plurality further averaging out the multiple hotspots over the target cell.

In some embodiments, the optical surfaces are modified, typically by lenticulation (i.e., the formation on a single surface of multiple independent lenslets that correspond to the segments mentioned before) to produce Köhler integration. Although the modified optical surfaces behave optically quite differently from the originals, they are macroscopically very similar to the unmodified surface. This means that they can be manufactured with the same techniques (typically plastic injection molding or glass molding) and that their production cost is the same.

An embodiment of the invention provides an optical device comprising: a primary optical element having a plurality of segments, which in an example are four in number; and a secondary optical element having a plurality of segments, which in an example are four lenticulations of an optical surface of a lens; wherein each segment of the primary optical element, along with a corresponding segment of the secondary optical element, forms one of a plurality of Köhler integrators. The plurality of Köhler integrators are arranged in position and orientation to direct light from a common source onto a common target. The common source, where the device is a light collector, or the common target, where the device is a luminaire, may be external to the device. For example, in the case of a solar photovoltaic concentrator, the source is the sun. Whether it is the common source or the common target, the other may be part of the device or connected to it. For example, in a solar photovoltaic concentrator, the target may be a photovoltaic cell. Further embodiments of the device, however, could be used to concentrate or collimate light between an external common source and an external common target.

### BRIEF DESCRIPTION OF THE DRAWINGS

The above and other aspects, features and advantages of the present invention will be apparent from the following more particular description thereof, presented in conjunction with the following drawings wherein:

FIG. 1 shows design rays used for calculating the desired shape of a radial Köhler refractive lenticulation pair.

FIG. 2 shows certain principles of the Fresnel-SILO concentrator developed by Sandia Labs.

FIG. 3 shows a two mirror Cassegrain-type reflective concentrator of sunlight.

FIG. 4A shows a perspective view of a quad-lenticular XXR Köhler concentrator that uses azimuthal integration.

FIG. 4B shows aside view of the quad-lenticular XXR Köhler concentrator of FIG. 4A.

FIG. 5 is a first diagram of a design process for the concentrator shown in FIG. 4A.

FIG. 6 is a second diagram of the design process of FIG. 5.

FIG. 7 is a third diagram of the design process of FIG. 5.

FIG. 8 is a fourth diagram of the design process of FIG. 5.

FIG. 9 is a perspective view similar to part of FIG. 4A, illustrating a second stage of the design process of FIGS. 5 to 8.

FIG. 10A is an axial sectional view of another embodiment of XXR concentrator, showing ray paths in the plane of section.

FIG. 10B is a perspective view of the concentrator of FIG. 10A, showing ray paths over the whole area of the optical elements.

FIG. 11 is a graph of the performance of the concentrator of FIG. 10A.

FIG. 12A is an axial sectional view of another form of concentrator.

FIG. 12B is a perspective view of the concentrator of FIG. 12A.

FIG. 12C is a perspective view of a further form of concentrator.

FIG. 13 is a perspective view of another form of concentrator.

FIG. 14 is an axial sectional view of a further form of concentrator.

FIG. 15A is a perspective view of another form of concentrator.

FIG. 15B is an enlarged view of one mirror of the concentrator of FIG. 15A.

### DETAILED DESCRIPTION OF THE EMBODIMENTS

A better understanding of various features and advantages of the present invention may be obtained by reference to the following detailed description of embodiments of the invention and accompanying drawings, which set forth illustrative embodiments in which various principles of the invention are utilized.

Two types of secondary optical elements are described herein: one comprising an array of refractors, the second an array of reflectors. Both exhibit overall N-fold symmetry. In the embodiments taught in this specification the primary reflective elements have the same N-fold symmetry as the secondary optic. In some embodiments the primary is asymmetric so the rest of elements are not located in front of the primary but on the side. Two types of intermediate optical elements are described herein: reflective type, and refractive type. The reflective intermediate optical element folds the ray path, permitting the removal of the secondary optical element and the solar cell (and heat-sink) from in front of the primary.

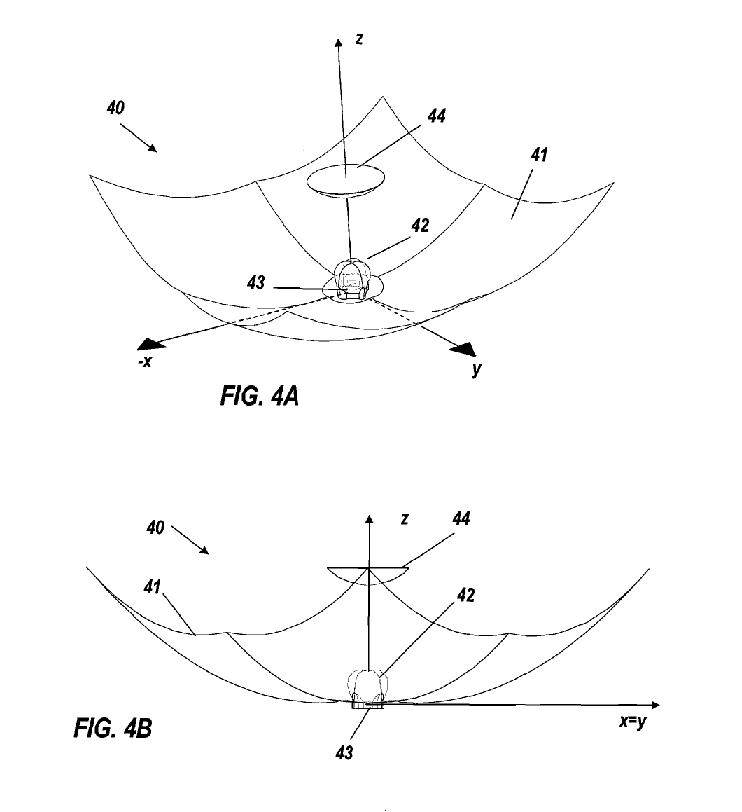

As may be seen from FIGS. 4 and 9 to 10B, symmetrical XXR configurations allow the photovoltaic cell to be placed close to, at, or even behind the primary mirror. Heat can then be removed to the rear of the primary mirror, greatly reducing the cooling problems of some prior designs, and the mounting for the PV cell can also be provided behind the primary mirror. Suitable heat sinks and mountings, are already known, and in the interests of clarity have been omitted from the drawings.

Several Köhler integrating solar concentrators are described herein. They are the first to combine a non flat array of Köhler integrators with concentration optics. Although, the embodiments of the invention revealed herein have quadrant symmetry, the invention does not limit embodiments to this symmetry but can be applied, by those skilled in the art, to other configurations (preferably N-fold symmetry, where N can be any number greater than two) once the principles taught herein are fully understood.

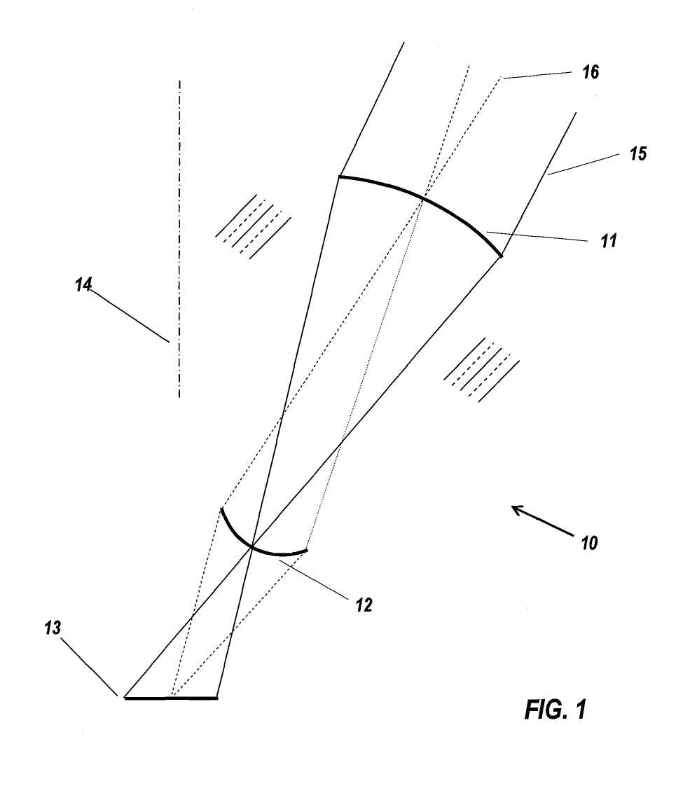

FIG. 1 shows lenticulation 10, comprising two refractive off-axis surfaces, primary optical element (POE) 11 and secondary optical element (SOE) 12, through which a light source outside the drawing illuminates cell 13. The final Radial Köhler concentrator will be the combination of several such lenticulation pairs, with common rotational axis 14 shown as a dot-dashed line. Solid lines 15 define the spatial edge rays and dotted lines 16 define the angular edge rays. They show the behavior of parallel and converging rays, respectively. In an embodiment, each optical element lenticulation 11, 12 may be one or more optical surfaces, each of which may be continuous or subdivided. For example, POE 11 may be a Fresnel lens, with one side flat and the other side formed of arcuate prisms.

Radial Köhler concentrators are 1D Köhler integrators with rotational symmetry. This makes the design process much easier than a 1D free-form Köhler integrator. Furthermore, rotational symmetry makes the manufacturing process as simple for a lenticular form as for any other aspheric rotational symmetry. The design process, however, first designs a 2D optical system, and then applies rotational symmetry.

Although the irradiance distribution produced by a radial Köhler concentrator has a hotspot, it is much milder than that produced by an imaging system. If α is the system acceptance angle, αₛ is the sun's angular radius, and k is a constant that depends on the shape of the cell's active area (where k=1 for a round cell and k=4/π for a square cell), it can easily be seen that the hotspot generated by a radial Köhler approach is proportional to k*(α/αₛ) times the average optical concentration, while the hotspot generated by an aplanatic device is proportional to k*(α/αₛ)² times the average optical concentration. For instance, if α=1°, αₛ=¼° (the angular radius of the sun as seen from Earth), and k=1, the hotspot created by a radial Köhler is around 4 times the average concentration, while the aplanatic design produces a hotspot 16 times the average concentration. For a square cell (k=4/π) the corresponding hotspots are 5 and 20 times the average concentration.

The radial Köhler concept has been applied in CPV systems to a two-mirror Cassegrain-type reflective concentrator (see Reference [15] and above-referenced WO 2007/103994). FIG. 3 shows a prior art two-mirror Cassegrain-type reflective concentrator 30, comprising lenticulated primary mirror 31, secondary mirror 32, and encapsulated solar cell 33 mounted on heat sink 34. Each concave reflector-lenticulation segment 31L is an annulus, and reflects incoming rays 35 as converging rays 36 focusing onto a corresponding annular lenticulation segment of secondary mirror 32, which in turn spreads them over cell 33, a 1 cm² cell of the triple junction type. Concentrator 30 is designed to work at C_{g}=650× with ±0.9° of acceptance angle, and has optical efficiency of 78%, with a maximum irradiance peak on the cell of 1200 suns. In the Radial Köhler design of FIG. 3, integration takes place only in the radial (meridional) direction, and not in the azimuthal or tangential (sagittal) direction. Also, the Kohler integrators are all different, because they are concentric rings, which both increases complexity and reduces uniformity. It is possible to configure the radial Köhler device to produce uniform irradiation of the photovoltaic cell with the sun on axis, but a hot spot then appears when the sun is off axis. In addition, Kohler integration with circular primary segments produces a circular irradiation on the photovoltaic cell, which is less than optimal because most commercially available PV cells are square.

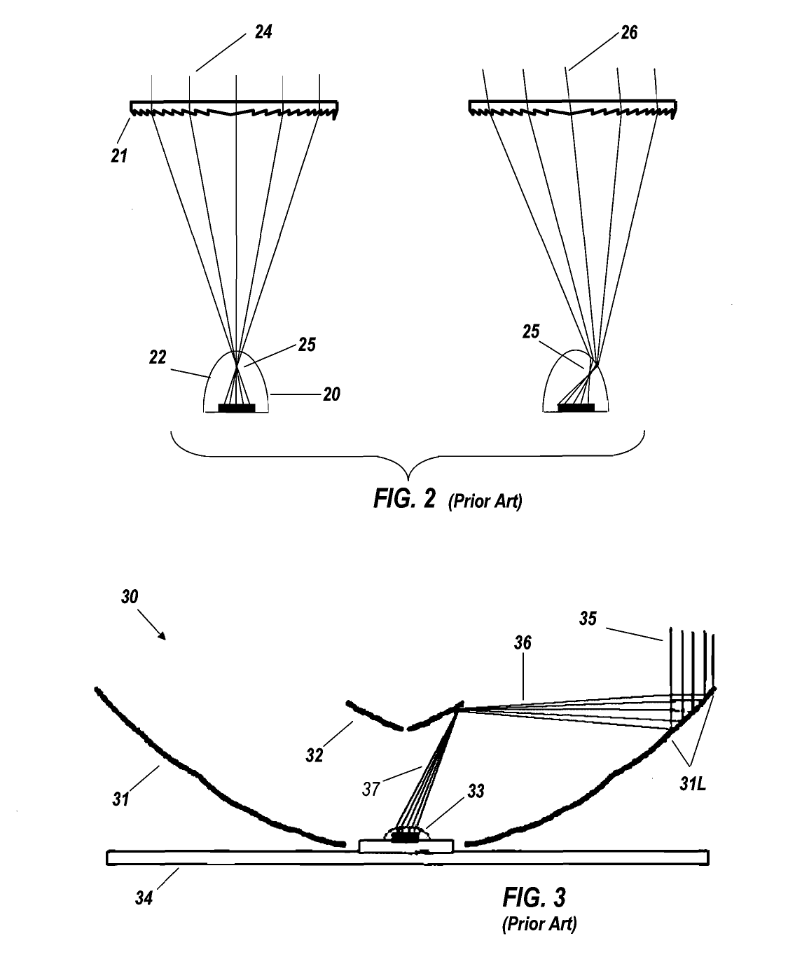

In this Radial Köhler design, the average concentration and the peak concentration can be high, so that it is necessary to introduce a further degree of freedom in the radial Köhler design, in order to keep the irradiance peak below 2000 suns. To perform the integration in a second direction, the present application comprises a concentrator with four subsystems (having quad-symmetry), hereinafter referred to as segments, that symmetrically compose a whole that achieves azimuthal integration, while keeping each of the four subsystems rotationally symmetric and thus maintaining ease of manufacture, since each is actually a part of a complete rotationally symmetric radial Köhler system, analogous to those of FIG. 2 and FIG. 3.

Better homogenization is produced when using a two-directional free-form Köhler integrator instead of a rotational-symmetric one. A possible type of free-form Köhler system is the same XXR, comprising a primary reflector, and intermediate reflector and a secondary refractor, in which the Kohler integration is performed between the primary and secondary elements. FIG. 4A and FIG. 4B show an embodiment of an XXR Köhler concentrator 40, comprising four-fold segmented primary mirror 41, four-fold segmented secondary lens 42, an intermediate mirror 44 and photovoltaic cell 43.

The photovoltaic receiver has preferably a square flat active area, and without loss of generality can be considered as located in a coordinate system in which the receiver plane is z=0 and the sides of the active area are parallel to the x and y axes, and the origin is in the center of the active area. Because of the symmetry, defining the unit in the region x>0, y>0 fully defines the primary optical element. The intermediate optical element will preferably have rotational symmetry around the z axis. The secondary optical element will preferably have the same four-fold symmetry as the primary. In the particular embodiment shown in FIG. 4A and FIG. 4B, the units of the primary and secondary optical elements in regions x>0, y>0 are Köhler pairs, but other correspondences are obviously possible.

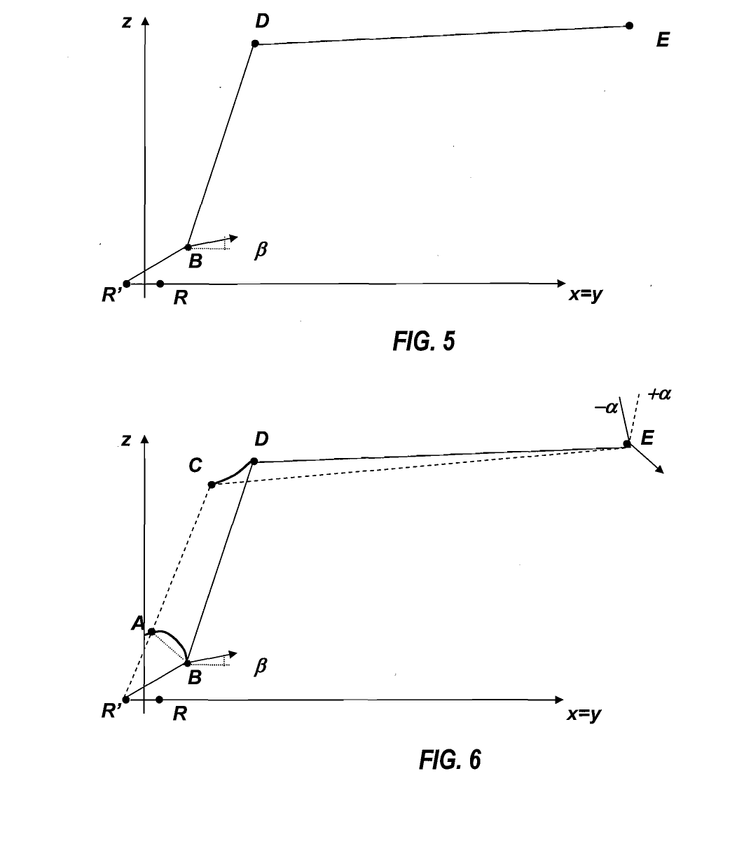

The design process has then three stages. First, the diagonal cross section profiles of the primary and intermediate mirrors are designed as in two dimensions using the SMS2D method (detailed below) with the conditions that the edge rays impinging on the entry aperture tilted +α and −α (α being the design acceptance angle) are focused in two dimensions (i.e., all the rays are contained in a plane) on close to the boundary points A and B of its corresponding lenticulation of the secondary lens, see FIG. 5. Second and third stages correspond to the design in three dimensions of the free-form surface of the primary and secondary, respectively.

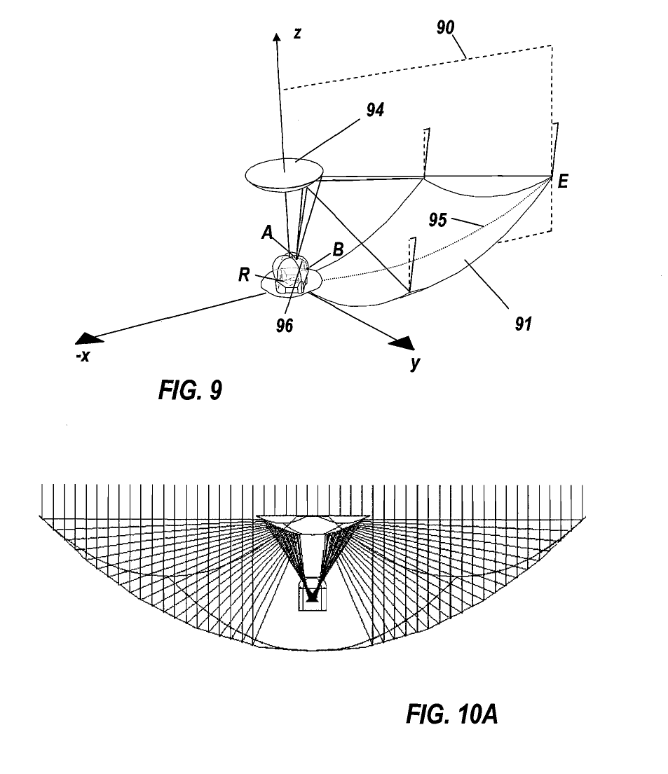

The first stage of the design is done with the following process, illustrated by FIG. 5 to FIG. 8, and generates a cross-section through the three optical surfaces in the x=y plane 90 (see FIG. 9).

1. Choose β, which is the direction of the normal to the optical surface at B.

2. Choose the x coordinates of R (& R′), which are the corner points of the active area of the PV cell 43, the x and z coordinates of point B and of point E, which is the outer corner of the selected lenticulation of the primary 41, and the z coordinate of point D, which is on the rim of the intermediate optical element 44.

3. Calculate the x coordinate of D by tracing the reversed ray R′-B-D.

4. Calculate the optical path length R′-B-D-E.

5. Choose α.

6. Calculate the normal vector at E so as to reflect the known reversed ray D-E into the direction −α.

7. Choose the z coordinate z_{A} of point A, Calculate the x coordinate of point A using the formula x_{A}=(2^{1/2}−1)/(2^{1/2}+1)x_{B}.

8. Calculate the line of the intermediate mirror from D to C as a “distortion-free imaging oval” so that there is a linear mapping between tilt (sin) angles of rays at E in the range +/−α and points along the straight segment A to B. (See FIG. 6).

9. Calculate the points of the secondary lens, starting from B, so that the rays from E reflected off the intermediate mirror are focused by refraction to R′ (using the optical path length condition, if desired). This is most conveniently done at the same time each point of the intermediate mirror is calculated.

10. The secondary lens calculated in step 9 will usually not pass through the previously chosen point A. The intersection of the secondary lens with the line x=x_{A} gives a better estimation of z_{A}. So go back to step 7, substitute the new value of z_{A}, and do an “iteration loop of z_{A},” repeating steps 8 and 9, and optionally repeating this step 10.

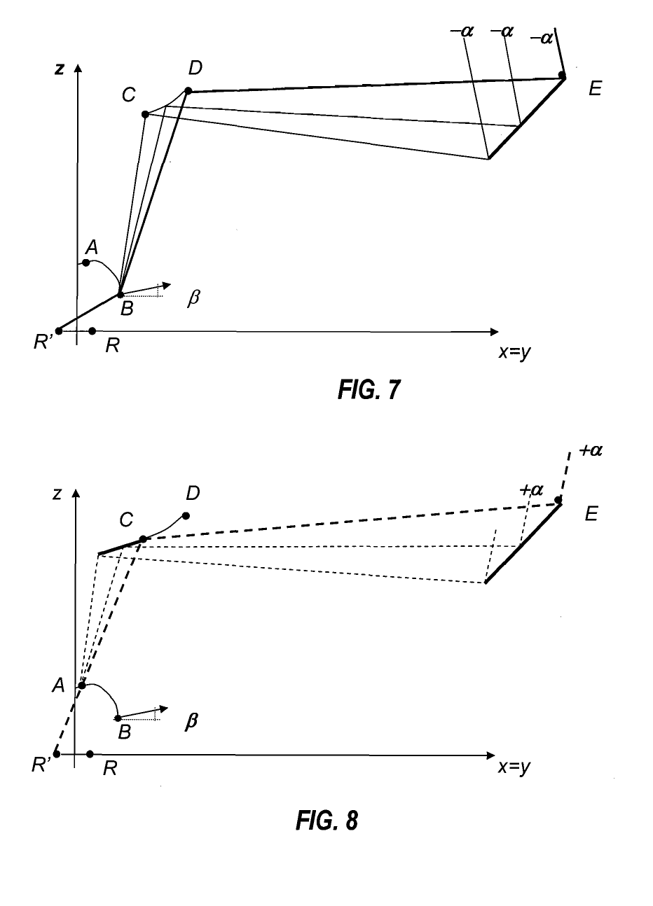

11. Calculate the primary and intermediate mirrors with SMS2D to form an image of the incident light from angle −α in B and of the incident light from angle +α in A. (See FIGS. 7 and 8.)

12. When the primary arrives at the z-axis, if the ray from +α at G after refraction at A does not reach R but a different point R″ on the receiver surface, go back to step 5 and choose a better a with value α *|R′R|/|R′R″|. Then repeat the subsequent steps.

13. If the x-coordinate of the last calculated point of the intermediate mirror (i.e., the closest to the z-axis) is not properly allocated (for instance, is negative), go back to step 2 and choose a different value for the coordinate x_{B} of point B. Then repeat the subsequent steps.

14. Generate the three-dimensional intermediate mirror by revolution of the profile with respect to the z-axis.

In the second stage of the design, illustrated in FIG. 9, the section x>0, y>0 of primary optical element 91 is designed in three-dimensions as the free-form mirror that forms an approximate image of the sun on the paired section of the secondary optical element through the rotationally symmetric intermediate mirror 94. Such a free-form primary mirror can be designed, for instance, as the Generalized reflective Cartesian oval that focuses all the +α rays in three dimensions, which are parallel to direction (−sin α, −sin α, −cos α), onto the point A after reflection on the intermediate mirror.

In the third step of the design, the secondary free-form lens is designed to form an image of the paired section of the primary optical element, reflected in the intermediate optical element, on the solar cell. Again, such a free-form lens can be designed, for instance, as the Generalized refractive Cartesian oval that receives rays passing through corner point E of the primary and reflected on the rotational intermediate mirror, and focuses them in three dimensions on the corner point R of the cell.

Note that the calculation in three dimensions of the primary and secondary is consistent with the two dimensional design, which means that the curves 95 and 96 contained in the free-form mirror and lens at the intersection of the diagonal x=y plane 90 in FIG. 9A coincide with the profiles calculated in the two-dimensional plane of FIG. 5 to FIG. 8.

The contour of the primary mirror in three dimensions is given by the image of the photovoltaic cell projected by the secondary lens. A notional cell larger than the real cell can be considered here, to allow for cell placement tolerances. The minimum contour size of the secondary lens units is defined by the image of the three-dimensional acceptance area (that is, the cone of radius α).

The intermediate mirror designed as described in the first stage differs very significantly from the aplanatic two mirror imaging design used in reference [6]. The aplanatic design produced focusing of the on-axis input rays onto an on-axis point, while the focal region of the on-axis input rays in the intermediate mirror designed according to the present embodiment is approximately centered in the off-axis segment AB. The difference is specially clear if the three-dimensional design is done using the intermediate mirror described in reference [6] and both +α rays and −α rays are traced as in FIG. 7 and FIG. 8, respectively. Even though the primary mirror is redesigned in three dimensions to perfectly focus the +a rays (rays incident parallel to (−sin α, −sin α, −cos α)) onto A, the use of the mirror of reference [6] as the intermediate optical element causes the focal region of the −α rays (parallel to (+sin α, +sin α, −cos α)) to be formed very far from the rim B of the secondary, specifically at a much higher z.

In another preferred embodiment, the intermediate mirror is also free-form and the primary and intermediate mirrors are designed using the SMS3D method, so four edge rays of the acceptance angle cone are approximately focused on four points at the rim of its corresponding lenticulation of the secondary in 3D geometry.

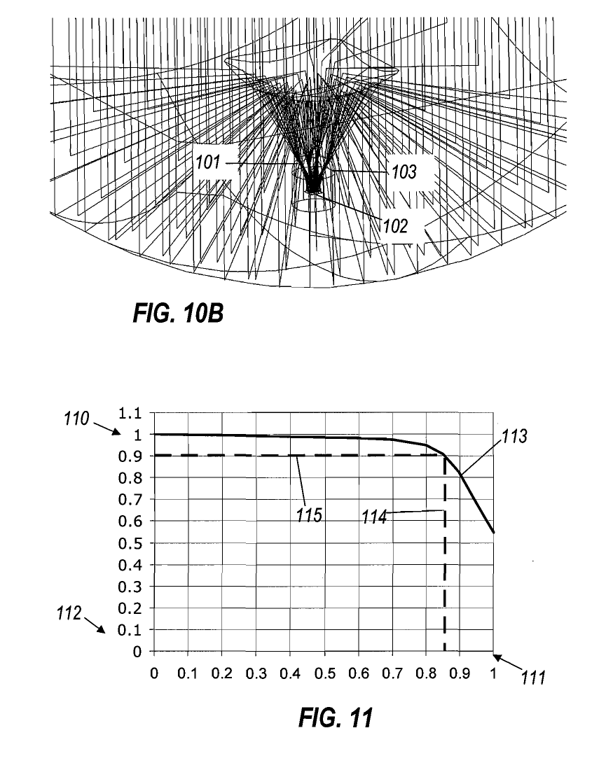

Referring to FIGS. 10A and 10B (collectively “FIG. 10”), FIG. 10A shows an XXR system similar to that of FIG. 4B with rays contained in a diagonal plane. FIG. 10B shows a close-up view of converging rays (in this case traced though the whole aperture) focusing to points 101 on the surface of secondary lens 103 (shown de-emphasized), and then spread out to uniformly cover cell 102. The irradiance thereupon is the sum of the four images of the primary mirror segments.

An embodiment of the XXR Köhler in FIG. 10 achieves a geometric concentration Cg=2090× (ratio of primary projected aperture area to cell area) with an acceptance of ±0.85°, which is a very good result for this concentration level as compared to the prior art. This high concentration level allows reduced cell costs in the system, and the acceptance angle is still high enough to provide the manufacturing tolerances needed for low cost. Shadowing of primary mirror 41 by intermediate mirror 45 is smaller than 5%.

FIG. 11 shows graph 110 with abscissa 111 plotting off-axis angle and ordinate 112 plotting relative transmission 113 of the XXR Köhler in FIG. 10. Vertical dashed line 114 corresponds to 0.85°, and horizontal dashed line 115 corresponds to the 90% threshold at which the acceptance angle is defined. The spectral dependence of the optical performance (optical efficiency, acceptance angle and irradiance distribution) is very small (which is an advantage of using mirrors).

Tables 1 to 3 (placed at the end of the description) provide an example of a concentrator according to FIG. 10. Table 1 contains the X-Y-Z coordinates of points of the free-form primary mirror of said design. The points correspond to the octant X>0, Y>X. Corresponding points in the remaining octants can be generated by interchanging the X and Y coordinates and/or changing the sign of the X and/or Y coordinate. Table 2 contains the p-Z coordinates of the profile points of the intermediate mirror. Since the design is rotationally symmetric, the whole mirror can be generated by rotation of the given coordinates around the Z axis. Finally, Table 3 contains the X-Y-Z coordinates of points of the free-form secondary lens of said design, also in the octant X>0, Y>X.

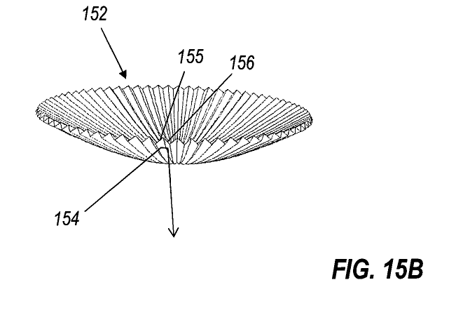

FIG. 15A shows a device 150 which is a modification of the XXR design of FIG. 10 using grooved reflectors 151 and 152 and the same secondary 153 as in FIG. 10. Grooved reflectors are described in U.S. patent application Ser. No. 12/456,406 (Publication Number: US 2010/0002320 A) titled “Reflectors Made of Linear Grooves,” filed 15 Jun. 2009, which is incorporated herein by reference in its entirety, and in which is disclosed how arbitrary rotational aspheric and free-form mirrors can be substituted by dielectric free-form structured equivalents that work by Total Internal Reflection (TIR). TIR is of interest in this XXR device to reduce the reflection losses due to metallic reflection, save the mirror coating cost and avoid the risk of the metal coating corrosion. FIG. 15B shows a detail of the intermediate mirror 152, and the ray 154 coming from the primary is twice totally internal reflected on free-form facets 155 and 156. In a CPV implementation, the mirrors 150, 152 are typically formed as the back surfaces of thin sheets of transparent material. In FIGS. 15A and 15B the refractive front surfaces of the dielectric grooved reflectors are not shown for clarity. In other embodiments, the space between the grooved reflectors 150, 152 may be a solid block of dielectric material with the grooved reflectors formed on opposite surfaces.

The present embodiments are a particular realization of the devices described in the above-mentioned patent application WO 2007/016363 to Miñano et al.

Variations can be obtained by designers skilled in the art. For instance, the number of cells, also called sections or lenslets, on each of the primary and secondary optical elements can be increased, for instance, to nine. Also the cell can be rectangular and not square, and then the four units of the primary mirror will preferably be correspondingly rectangular, so that each unit still images easily onto the photovoltaic cell. Alternatively, or in addition, the number of array units could be reduced to two, or could be another number that is not a square, so that the overall primary is a differently shaped rectangle from the photovoltaic cell. Where each segment is further subdivided into lenslets, the desirable number of lenslets in each primary and secondary lens segment may depend on the actual size of the device, as affecting the resulting size and precision of manufacture of the lens features.

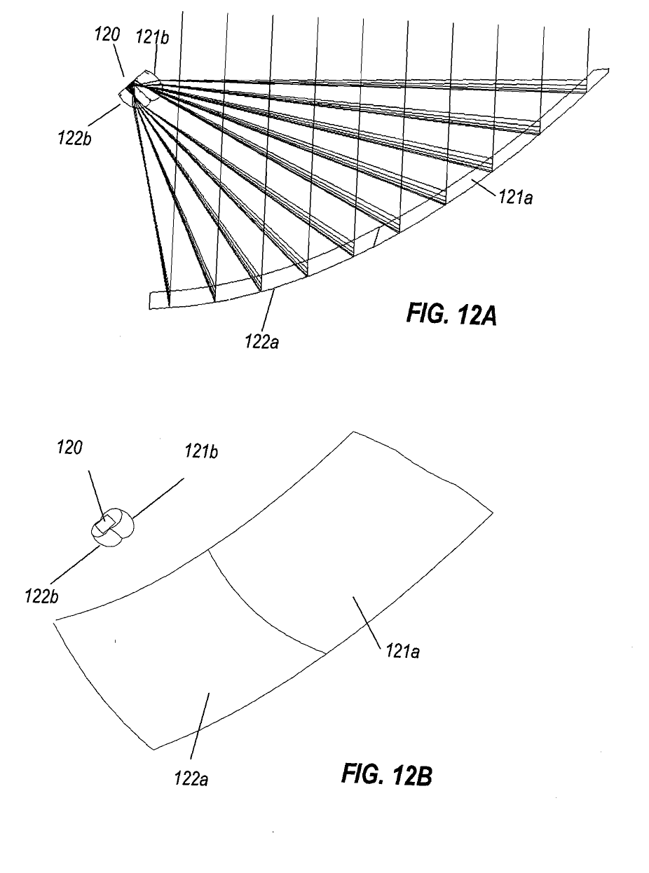

Examples of such variations are shown in FIG. 12A to FIG. 14. FIGS. 12A and 12B show an embodiment of a two-unit array XR concentrator comprising an asymmetric tilted primary mirror and a refractive secondary to illuminate solar cell 120, so no intermediate optical element is used in this case. The Kohler pairs are 122a-122b and 121a-121b. The tilt of the mirror allows the secondary to be placed outside the beam of light incident on the primary, avoiding the shading produced by the secondary and heat sink in conventional centered systems. FIG. 12C shows a similar XR configuration with Kohler integration using four units: 123a to 136a and 123b to 126b.

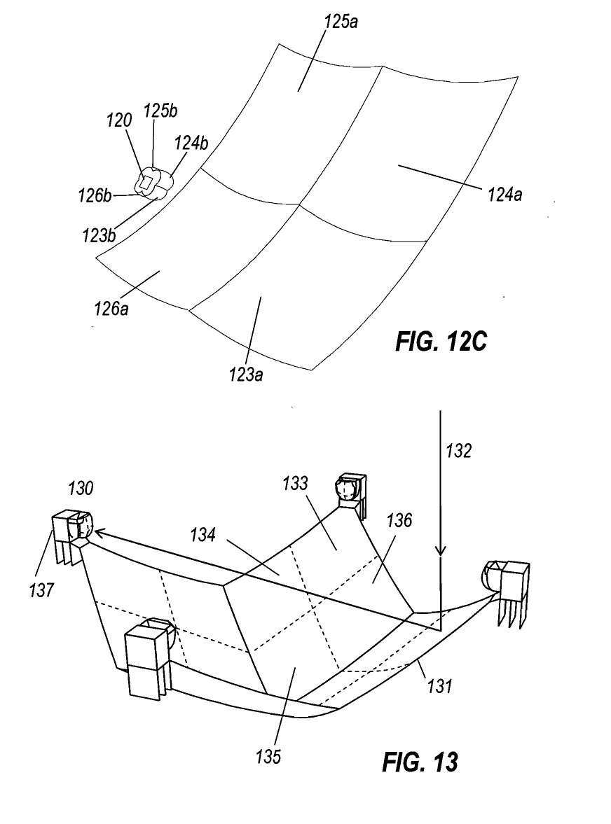

FIG. 13 shows a four-unit tilted XR, in which compared to the previous ones the unit is rotated 45 degrees with respect to an axis normal to its surface passing through its center, so the full primary mirror 131 shows the same 45 degree rotation. Each unit has its own secondary lens 130 and PV cell 137 placed at the outer corner of the primary mirror opposite its own primary mirror 131, in the arrangement shown in FIG. 13. Note that the primary 131 receives light from the sun as shown by ray 132 and illuminates the PV cell located behind the secondary 130. Each primary mirror 131 and each secondary lens 130 is segmented into the Kohler lenticulations, as 133 to 136. This relative positioning of the primaries and secondaries allows the whole primary to be supported from the secondary positions at the corners, and even the heatsink 137 can be extended along the perimeter to become a supporting frame that eventually can also support a front glass cover.

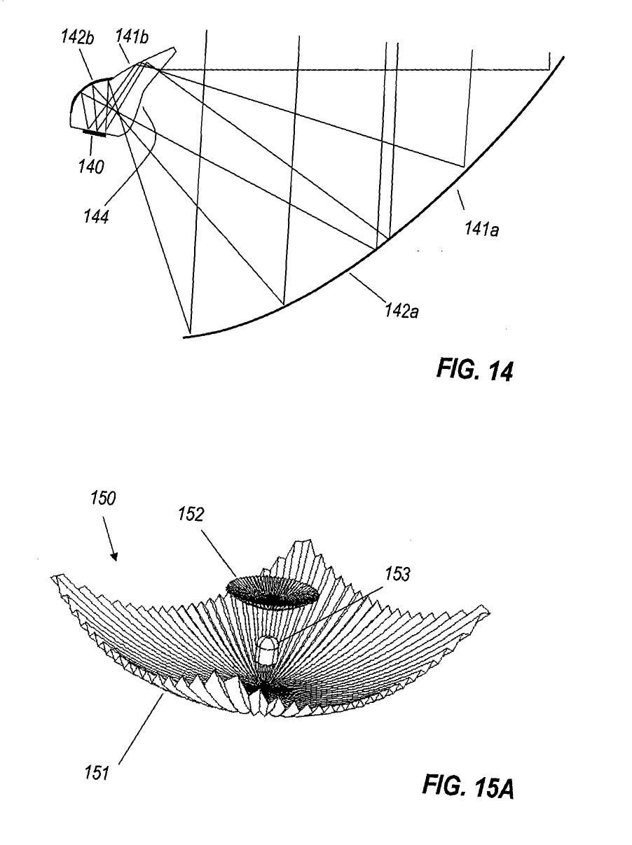

FIG. 14 shows an example in which the intermediate optical surface 144 is not a mirror but a lens, while both primary (141a and 142a) and secondary Kohler integrating surfaces (141b and 142b) work by reflection. One secondary reflector 141b is metalized (XRX) and the other is a TIR surface (XRI).

Although various specific embodiments have been shown and described, the skilled reader will understand how features of different embodiments may be combined in a single photovoltaic collector, luminaire, or other device to form other devices within the scope of the present invention. When the photovoltaic cell is replaced by an LED or an LED array, or other light source, the present embodiments provide optical devices that can collimate the light with a quite uniform intensity for the directions of emission, because all points on the source are carried to every direction. This can be used to mix the colors of different LEDs of a source array or to make the intensity of the emission more uniform without the need to bin the chips.

The preceding description of the presently contemplated best mode of practicing the invention is not to be taken in a limiting sense, but is made merely for the purpose of describing the general principles of the invention. The full scope of the invention should be determined with reference to the Claims.

TABLE 1

| x | y | z |
|---|---|---|
| 192.287 | 195.167 | 58.140 |
| 56.261 | 163.672 | −12.523 |
| 57.652 | 167.477 | −10.307 |
| 1.976 | 2.092 | −57.289 |
| 1.719 | 2.311 | −57.288 |
| 1.168 | 2.702 | −57.285 |
| 0.578 | 3.028 | −57.281 |
| −0.041 | 3.290 | −57.274 |
| 5.427 | 5.579 | −57.309 |
| 4.679 | 6.201 | −57.308 |
| 3.873 | 6.744 | −57.305 |
| 3.453 | 6.985 | −57.302 |
| 2.581 | 7.407 | −57.296 |
| 2.134 | 7.587 | −57.292 |
| 1.221 | 7.889 | −57.283 |
| 0.758 | 8.011 | −57.278 |
| 0.058 | 8.159 | −57.269 |
| 9.454 | 9.667 | −57.230 |
| 8.171 | 10.737 | −57.228 |
| 7.065 | 11.481 | −57.225 |
| 6.489 | 11.815 | −57.222 |
| 5.300 | 12.404 | −57.215 |
| 4.690 | 12.660 | −57.211 |
| 3.446 | 13.095 | −57.200 |
| 2.814 | 13.274 | −57.194 |
| 2.178 | 13.428 | −57.187 |
| 0.896 | 13.662 | −57.172 |
| 0.253 | 13.743 | −57.164 |
| 12.965 | 13.232 | −57.085 |
| 11.397 | 14.580 | −57.083 |
| 10.052 | 15.538 | −57.079 |
| 9.353 | 15.975 | −57.076 |
| 7.910 | 16.764 | −57.068 |
| 7.168 | 17.115 | −57.063 |
| 5.652 | 17.732 | −57.050 |
| 4.880 | 17.997 | −57.043 |
| 3.313 | 18.443 | −57.026 |
| 2.522 | 18.623 | −57.017 |
| 0.927 | 18.899 | −56.996 |
| 0.125 | 18.996 | −56.984 |
| 19.039 | 19.394 | −56.643 |
| 18.231 | 20.140 | −56.644 |
| 16.530 | 21.533 | −56.642 |
| 14.730 | 22.789 | −56.637 |
| 13.797 | 23.364 | −56.634 |
| 11.874 | 24.406 | −56.624 |
| 10.887 | 24.873 | −56.618 |
| 8.870 | 25.698 | −56.603 |
| 7.843 | 26.057 | −56.594 |
| 5.759 | 26.666 | −56.574 |
| 4.705 | 26.916 | −56.562 |
| 1.508 | 27.453 | −56.521 |
| −0.102 | 27.602 | −56.497 |
| 22.715 | 23.123 | −56.261 |
| 20.824 | 24.804 | −56.261 |
| 19.832 | 25.587 | −56.260 |
| 17.764 | 27.035 | −56.256 |
| 15.598 | 28.321 | −56.249 |
| 14.483 | 28.902 | −56.244 |
| 12.196 | 29.939 | −56.231 |
| 11.029 | 30.395 | −56.223 |
| 8.654 | 31.180 | −56.205 |
| 7.449 | 31.510 | −56.194 |
| 5.015 | 32.045 | −56.169 |
| 3.788 | 32.251 | −56.155 |
| 1.323 | 32.539 | −56.124 |
| 0.086 | 32.623 | −56.107 |
| 26.721 | 26.173 | −55.821 |
| 25.697 | 27.162 | −55.822 |
| 24.638 | 28.112 | −55.822 |
| 22.420 | 29.890 | −55.819 |
| 20.080 | 31.497 | −55.813 |
| 18.870 | 32.236 | −55.809 |
| 16.378 | 33.580 | −55.796 |
| 15.099 | 34.185 | −55.789 |
| 12.486 | 35.258 | −55.770 |
| 11.155 | 35.726 | −55.758 |
| 8.452 | 36.524 | −55.732 |
| 7.083 | 36.854 | −55.718 |
| 4.318 | 37.374 | −55.685 |
| 1.529 | 37.710 | −55.647 |
| 0.129 | 37.808 | −55.626 |
| 30.068 | 30.583 | −55.222 |
| 28.898 | 31.669 | −55.224 |
| 27.687 | 32.708 | −55.224 |
| 25.800 | 34.178 | −55.224 |
| 23.165 | 35.966 | −55.222 |
| 21.802 | 36.785 | −55.219 |
| 18.996 | 38.269 | −55.211 |
| 16.098 | 39.549 | −55.199 |
| 13.874 | 40.374 | −55.187 |
| 10.854 | 41.294 | −55.167 |
| 9.325 | 41.676 | −55.155 |
| 6.237 | 42.288 | −55.126 |
| 4.681 | 42.517 | −55.110 |
| 1.557 | 42.821 | −55.073 |
| −0.009 | 42.897 | −55.053 |
| 34.298 | 34.875 | −54.472 |
| 31.643 | 37.265 | −54.473 |
| 30.252 | 38.385 | −54.472 |
| 27.356 | 40.468 | −54.468 |
| 25.092 | 41.888 | −54.462 |
| 23.544 | 42.766 | −54.457 |
| 20.363 | 44.355 | −54.443 |
| 18.734 | 45.065 | −54.435 |
| 16.250 | 46.022 | −54.419 |
| 14.570 | 46.589 | −54.407 |
| 12.017 | 47.330 | −54.387 |
| 10.297 | 47.752 | −54.371 |
| 6.822 | 48.420 | −54.336 |
| 3.314 | 48.855 | −54.296 |
| 1.552 | 48.985 | −54.274 |
| −0.211 | 49.056 | −54.250 |
| 40.643 | 41.311 | −53.125 |
| 37.574 | 44.096 | −53.126 |
| 34.320 | 46.656 | −53.121 |
| 30.898 | 48.980 | −53.112 |
| 27.329 | 51.063 | −53.097 |
| 23.629 | 52.897 | −53.076 |
| 19.815 | 54.478 | −53.048 |
| 15.907 | 55.802 | −53.014 |
| 11.920 | 56.865 | −52.972 |
| 7.871 | 57.666 | −52.923 |
| 3.777 | 58.201 | −52.867 |
| 1.719 | 58.369 | −52.836 |
| −0.344 | 58.469 | −52.804 |
| 43.944 | 44.660 | −52.319 |
| 42.325 | 46.180 | −52.321 |
| 40.653 | 47.642 | −52.321 |
| 37.163 | 50.382 | −52.319 |
| 35.350 | 51.657 | −52.315 |
| 32.551 | 53.449 | −52.308 |
| 30.637 | 54.562 | −52.302 |
| 26.702 | 56.587 | −52.285 |
| 24.687 | 57.498 | −52.274 |
| 20.572 | 59.115 | −52.246 |
| 18.477 | 59.820 | −52.230 |
| 14.224 | 61.020 | −52.191 |
| 12.070 | 61.515 | −52.169 |
| 7.719 | 62.293 | −52.120 |
| 5.527 | 62.575 | −52.092 |
| 0.015 | 62.969 | −52.014 |
| 51.111 | 51.931 | −50.333 |
| 47.346 | 55.353 | −50.335 |
| 44.373 | 57.740 | −50.334 |
| 42.325 | 59.244 | −50.331 |
| 39.161 | 61.364 | −50.325 |
| 36.994 | 62.685 | −50.318 |
| 34.784 | 63.932 | −50.310 |
| 32.534 | 65.103 | −50.301 |
| 30.247 | 66.198 | −50.289 |
| 27.925 | 67.216 | −50.276 |
| 25.570 | 68.156 | −50.260 |
| 23.186 | 69.019 | −50.243 |
| 20.775 | 69.803 | −50.223 |
| 18.340 | 70.507 | −50.201 |
| 15.882 | 71.132 | −50.176 |
| 13.405 | 71.677 | −50.150 |
| 10.910 | 72.141 | −50.121 |
| 8.402 | 72.525 | −50.090 |
| 5.881 | 72.827 | −50.056 |
| 3.351 | 73.047 | −50.021 |
| 0.814 | 73.184 | −49.983 |
| −0.456 | 73.221 | −49.963 |
| 55.323 | 56.204 | −48.984 |
| 51.268 | 59.873 | −48.990 |
| 48.064 | 62.427 | −48.993 |
| 45.855 | 64.032 | −48.994 |
| 42.443 | 66.291 | −48.994 |
| 40.106 | 67.695 | −48.993 |
| 37.724 | 69.017 | −48.990 |
| 35.298 | 70.256 | −48.986 |
| 32.833 | 71.412 | −48.980 |
| 30.332 | 72.483 | −48.973 |
| 27.797 | 73.469 | −48.963 |
| 25.231 | 74.369 | −48.952 |
| 22.637 | 75.184 | −48.939 |
| 20.019 | 75.913 | −48.924 |
| 17.378 | 76.555 | −48.906 |
| 14.718 | 77.110 | −48.887 |
| 12.041 | 77.578 | −48.865 |
| 9.351 | 77.959 | −48.840 |
| 6.649 | 78.252 | −48.814 |
| 3.940 | 78.457 | −48.785 |
| 1.226 | 78.574 | −48.754 |
| −0.132 | 78.600 | −48.737 |
| 62.828 | 63.819 | −46.338 |
| 58.291 | 67.964 | −46.339 |
| 54.710 | 70.864 | −46.336 |
| 52.244 | 72.693 | −46.332 |
| 45.824 | 76.892 | −46.313 |
| 41.813 | 79.148 | −46.295 |
| 39.079 | 80.539 | −46.281 |
| 36.300 | 81.838 | −46.264 |
| 33.479 | 83.046 | −46.245 |
| 30.620 | 84.159 | −46.224 |
| 27.724 | 85.179 | −46.200 |
| 24.796 | 86.103 | −46.174 |
| 21.838 | 86.931 | −46.145 |
| 18.853 | 87.662 | −46.114 |
| 15.845 | 88.296 | −46.080 |
| 12.815 | 88.831 | −46.043 |
| 9.769 | 89.268 | −46.004 |
| 6.707 | 89.605 | −45.963 |
| 3.635 | 89.842 | −45.918 |
| 0.555 | 89.979 | −45.872 |
| 65.901 | 66.937 | −45.142 |
| 61.161 | 71.270 | −45.144 |
| 57.420 | 74.301 | −45.140 |
| 54.844 | 76.214 | −45.136 |
| 48.138 | 80.607 | −45.117 |
| 45.358 | 82.204 | −45.105 |
| 42.526 | 83.707 | −45.091 |
| 39.646 | 85.116 | −45.075 |
| 36.721 | 86.429 | −45.057 |
| 33.753 | 87.645 | −45.036 |
| 30.746 | 88.764 | −45.013 |
| 27.704 | 89.783 | −44.987 |
| 24.628 | 90.703 | −44.958 |
| 21.522 | 91.522 | −44.927 |
| 18.390 | 92.239 | −44.893 |
| 15.234 | 92.855 | −44.856 |
| 12.058 | 93.368 | −44.816 |
| 8.865 | 93.777 | −44.774 |
| 4.052 | 94.195 | −44.706 |
| 0.831 | 94.344 | −44.657 |
| 75.988 | 77.170 | −40.786 |
| 70.575 | 82.117 | −40.791 |
| 63.362 | 87.761 | −40.787 |
| 54.124 | 93.697 | −40.768 |
| 47.658 | 97.129 | −40.744 |
| 44.344 | 98.682 | −40.729 |
| 37.569 | 101.458 | −40.689 |
| 30.624 | 103.788 | −40.637 |
| 27.095 | 104.782 | −40.607 |
| 23.535 | 105.661 | −40.573 |
| 16.332 | 107.072 | −40.497 |
| 12.697 | 107.602 | −40.453 |
| 5.378 | 108.309 | −40.357 |
| 1.701 | 108.484 | −40.304 |
| −0.140 | 108.527 | −40.276 |
| 80.478 | 81.726 | −38.607 |
| 74.754 | 86.936 | −38.617 |
| 67.119 | 92.865 | −38.627 |
| 57.340 | 99.076 | −38.632 |
| 50.498 | 102.648 | −38.627 |
| 46.991 | 104.260 | −38.622 |
| 39.829 | 107.128 | −38.604 |
| 32.491 | 109.517 | −38.577 |
| 28.767 | 110.530 | −38.559 |
| 25.011 | 111.420 | −38.538 |
| 17.419 | 112.831 | −38.487 |
| 13.591 | 113.350 | −38.457 |
| 5.890 | 114.014 | −38.387 |
| 2.026 | 114.158 | −38.347 |
| 0.092 | 114.183 | −38.326 |
| 85.008 | 86.323 | −36.318 |
| 78.994 | 91.826 | −36.322 |
| 70.980 | 98.107 | −36.319 |
| 60.715 | 104.718 | −36.299 |
| 53.528 | 108.538 | −36.275 |
| 49.842 | 110.267 | −36.260 |
| 40.394 | 114.046 | −36.210 |
| 34.582 | 115.936 | −36.172 |
| 30.658 | 117.036 | −36.143 |
| 26.697 | 118.006 | −36.112 |
| 18.684 | 119.553 | −36.040 |
| 14.641 | 120.129 | −36.000 |
| 6.502 | 120.880 | −35.911 |
| 2.416 | 121.054 | −35.863 |
| 0.370 | 121.091 | −35.837 |
| 94.197 | 95.645 | −31.214 |
| 87.579 | 101.716 | −31.216 |
| 78.766 | 108.658 | −31.206 |
| 75.085 | 111.225 | −31.197 |
| 65.531 | 117.096 | −31.165 |
| 61.579 | 119.220 | −31.147 |
| 57.558 | 121.214 | −31.126 |
| 53.474 | 123.075 | −31.101 |
| 45.127 | 126.394 | −31.043 |
| 36.573 | 129.163 | −30.970 |
| 32.229 | 130.338 | −30.929 |
| 27.846 | 131.371 | −30.884 |
| 18.980 | 133.008 | −30.783 |
| 14.506 | 133.609 | −30.727 |
| 10.011 | 134.065 | −30.667 |
| 0.978 | 134.536 | −30.537 |
| −1.286 | 134.562 | −30.502 |
| 97.395 | 98.890 | −29.308 |
| 90.566 | 105.157 | −29.310 |
| 81.470 | 112.325 | −29.299 |
| 77.672 | 114.975 | −29.291 |
| 67.812 | 121.038 | −29.258 |
| 63.733 | 123.232 | −29.240 |
| 59.584 | 125.291 | −29.218 |
| 55.368 | 127.213 | −29.193 |
| 46.753 | 130.641 | −29.134 |
| 37.924 | 133.500 | −29.061 |
| 33.440 | 134.713 | −29.019 |
| 28.915 | 135.780 | −28.974 |
| 19.763 | 137.469 | −28.872 |
| 15.145 | 138.089 | −28.816 |
| 10.506 | 138.558 | −28.756 |
| 1.181 | 139.042 | −28.625 |
| −1.156 | 139.067 | −28.590 |
| 107.402 | 109.043 | −22.913 |
| 99.909 | 115.927 | −22.915 |
| 89.931 | 123.805 | −22.902 |
| 85.764 | 126.720 | −22.891 |
| 79.341 | 130.831 | −22.870 |
| 74.949 | 133.393 | −22.852 |
| 68.208 | 136.963 | −22.819 |
| 63.618 | 139.157 | −22.792 |
| 58.957 | 141.201 | −22.762 |
| 49.440 | 144.827 | −22.691 |
| 42.150 | 147.137 | −22.628 |
| 37.227 | 148.478 | −22.582 |
| 32.259 | 149.658 | −22.531 |
| 22.208 | 151.531 | −22.419 |
| 17.136 | 152.221 | −22.357 |
| 12.039 | 152.744 | −22.291 |
| 1.795 | 153.290 | −22.149 |
| −0.773 | 153.321 | −22.111 |
| 111.075 | 112.769 | −20.379 |
| 103.326 | 119.870 | −20.387 |
| 93.005 | 127.983 | −20.389 |
| 88.694 | 130.980 | −20.387 |
| 79.786 | 136.534 | −20.375 |
| 75.200 | 139.087 | −20.366 |
| 70.531 | 141.486 | −20.354 |
| 65.785 | 143.731 | −20.338 |
| 60.966 | 145.818 | −20.320 |
| 51.132 | 149.516 | −20.272 |
| 43.603 | 151.864 | −20.227 |
| 38.520 | 153.224 | −20.192 |
| 33.392 | 154.418 | −20.153 |
| 23.024 | 156.304 | −20.063 |
| 17.793 | 156.993 | −20.011 |
| 12.539 | 157.511 | −19.956 |
| 1.983 | 158.033 | −19.832 |
| −0.662 | 158.055 | −19.799 |
| 121.459 | 123.305 | −12.789 |
| 113.030 | 131.058 | −12.789 |
| 101.808 | 139.934 | −12.772 |
| 97.123 | 143.220 | −12.759 |
| 87.440 | 149.322 | −12.723 |
| 82.453 | 152.132 | −12.700 |
| 77.375 | 154.778 | −12.673 |
| 72.212 | 157.257 | −12.641 |
| 66.969 | 159.568 | −12.606 |
| 50.807 | 165.462 | −12.474 |
| 39.725 | 168.507 | −12.365 |
| 34.109 | 169.758 | −12.304 |
| 22.753 | 171.710 | −12.167 |
| 17.026 | 172.408 | −12.093 |
| 5.501 | 173.242 | −11.930 |
| −0.284 | 173.376 | −11.842 |
| 124.320 | 126.208 | −10.568 |
| 115.701 | 134.134 | −10.569 |
| 104.226 | 143.211 | −10.553 |
| 99.435 | 146.570 | −10.540 |
| 89.534 | 152.809 | −10.506 |
| 84.434 | 155.681 | −10.483 |
| 79.242 | 158.386 | −10.456 |
| 73.963 | 160.921 | −10.425 |
| 68.601 | 163.282 | −10.390 |
| 52.075 | 169.306 | −10.260 |
| 40.744 | 172.418 | −10.151 |
| 35.002 | 173.696 | −10.089 |
| 23.391 | 175.690 | −9.954 |
| 17.535 | 176.402 | −9.879 |
| 5.752 | 177.252 | −9.717 |
| −0.163 | 177.387 | −9.629 |
| 133.343 | 135.362 | −3.215 |
| 124.122 | 143.840 | −3.218 |
| 111.847 | 153.546 | −3.205 |
| 106.720 | 157.139 | −3.194 |
| 98.816 | 162.206 | −3.173 |
| 93.412 | 165.365 | −3.153 |
| 87.906 | 168.346 | −3.131 |
| 82.304 | 171.145 | −3.104 |
| 76.611 | 173.761 | −3.073 |
| 70.833 | 176.190 | −3.038 |
| 64.976 | 178.430 | −2.999 |
| 59.045 | 180.479 | −2.955 |
| 43.934 | 184.749 | −2.827 |
| 37.791 | 186.112 | −2.767 |
| 25.373 | 188.234 | −2.634 |
| 19.111 | 188.990 | −2.560 |
| 6.510 | 189.888 | −2.400 |
| 0.186 | 190.027 | −2.313 |
| 136.402 | 138.466 | −0.604 |
| 126.981 | 147.136 | −0.604 |
| 114.440 | 157.066 | −0.585 |
| 109.203 | 160.743 | −0.572 |
| 101.129 | 165.931 | −0.544 |
| 95.608 | 169.167 | −0.521 |
| 89.982 | 172.221 | −0.493 |
| 84.259 | 175.091 | −0.462 |
| 78.442 | 177.772 | −0.426 |
| 72.537 | 180.263 | −0.386 |
| 66.551 | 182.562 | −0.342 |
| 60.489 | 184.665 | −0.293 |
| 45.042 | 189.052 | −0.150 |
| 38.762 | 190.454 | −0.085 |
| 26.065 | 192.639 | 0.058 |
| 19.660 | 193.420 | 0.137 |
| 6.773 | 194.352 | 0.308 |
| 0.304 | 194.500 | 0.399 |
| 146.053 | 148.259 | 8.057 |
| 135.987 | 157.523 | 8.056 |
| 122.586 | 168.133 | 8.073 |
| 116.990 | 172.062 | 8.086 |
| 105.427 | 179.358 | 8.124 |
| 99.471 | 182.719 | 8.149 |
| 87.241 | 188.850 | 8.212 |
| 80.978 | 191.614 | 8.251 |
| 68.187 | 196.525 | 8.341 |
| 61.672 | 198.668 | 8.394 |
| 48.434 | 202.313 | 8.514 |
| 41.724 | 203.812 | 8.582 |
| 28.157 | 206.151 | 8.733 |
| 21.314 | 206.988 | 8.816 |
| 7.544 | 207.989 | 8.997 |
| 0.631 | 208.151 | 9.094 |
| 149.453 | 151.709 | 11.263 |
| 139.157 | 161.180 | 11.260 |
| 125.450 | 172.025 | 11.273 |
| 119.726 | 176.040 | 11.284 |
| 107.897 | 183.492 | 11.315 |
| 101.804 | 186.924 | 11.336 |
| 89.292 | 193.179 | 11.390 |
| 82.886 | 195.998 | 11.423 |
| 69.802 | 201.001 | 11.502 |
| 63.139 | 203.181 | 11.548 |
| 49.600 | 206.884 | 11.653 |
| 42.739 | 208.402 | 11.713 |
| 28.868 | 210.763 | 11.845 |
| 21.873 | 211.602 | 11.918 |
| 7.800 | 212.590 | 12.078 |
| 0.737 | 212.737 | 12.165 |
| 146.886 | 170.086 | 19.368 |
| 132.458 | 181.527 | 19.393 |
| 126.433 | 185.765 | 19.410 |
| 113.983 | 193.639 | 19.458 |
| 107.571 | 197.268 | 19.488 |
| 94.400 | 203.890 | 19.564 |
| 87.655 | 206.877 | 19.609 |
| 73.878 | 212.188 | 19.714 |
| 66.859 | 214.506 | 19.774 |
| 52.596 | 218.453 | 19.911 |
| 45.366 | 220.077 | 19.987 |
| 30.744 | 222.616 | 20.154 |
| 23.368 | 223.526 | 20.246 |
| 8.523 | 224.621 | 20.444 |
| 1.070 | 224.802 | 20.551 |
| 160.387 | 162.802 | 22.070 |
| 149.371 | 172.949 | 22.072 |
| 134.709 | 184.578 | 22.098 |
| 128.587 | 188.886 | 22.115 |
| 115.935 | 196.890 | 22.164 |
| 109.418 | 200.578 | 22.195 |
| 96.033 | 207.310 | 22.272 |
| 89.179 | 210.347 | 22.318 |
| 75.177 | 215.746 | 22.425 |
| 68.044 | 218.103 | 22.486 |
| 53.549 | 222.117 | 22.624 |
| 46.200 | 223.768 | 22.701 |
| 31.340 | 226.350 | 22.870 |
| 23.843 | 227.275 | 22.963 |
| 8.756 | 228.389 | 23.163 |
| 1.182 | 228.573 | 23.271 |
| 165.711 | 168.203 | 27.618 |
| 154.342 | 178.677 | 27.620 |
| 139.209 | 190.679 | 27.645 |
| 132.891 | 195.126 | 27.663 |
| 119.833 | 203.387 | 27.712 |
| 113.107 | 207.194 | 27.743 |
| 99.292 | 214.143 | 27.821 |
| 92.218 | 217.278 | 27.867 |
| 77.767 | 222.851 | 27.974 |
| 70.405 | 225.283 | 28.036 |
| 55.444 | 229.425 | 28.175 |
| 47.859 | 231.129 | 28.253 |
| 32.522 | 233.793 | 28.424 |
| 24.784 | 234.748 | 28.517 |
| 9.212 | 235.895 | 28.720 |
| 1.395 | 236.085 | 28.829 |
| 168.389 | 170.920 | 30.478 |
| 156.842 | 181.559 | 30.481 |
| 141.474 | 193.751 | 30.508 |
| 135.057 | 198.268 | 30.527 |
| 121.796 | 206.662 | 30.577 |
| 114.965 | 210.530 | 30.610 |
| 100.936 | 217.590 | 30.690 |
| 93.751 | 220.775 | 30.737 |
| 79.074 | 226.439 | 30.848 |
| 71.597 | 228.911 | 30.911 |
| 56.401 | 233.121 | 31.053 |
| 48.697 | 234.853 | 31.132 |
| 33.118 | 237.561 | 31.306 |
| 25.259 | 238.532 | 31.401 |
| 173.887 | 176.499 | 36.502 |
| 161.975 | 187.475 | 36.505 |
| 146.121 | 200.055 | 36.533 |
| 139.500 | 204.715 | 36.551 |
| 125.819 | 213.376 | 36.603 |
| 118.772 | 217.367 | 36.636 |
| 104.297 | 224.651 | 36.716 |
| 96.884 | 227.937 | 36.764 |
| 81.742 | 233.780 | 36.875 |
| 74.027 | 236.330 | 36.939 |
| 176.578 | 179.229 | 39.525 |
| 164.486 | 190.370 | 39.527 |
| 148.391 | 203.137 | 39.553 |
| 141.670 | 207.867 | 39.571 |
| 127.782 | 216.654 | 39.619 |
| 120.628 | 220.704 | 39.651 |
| 105.934 | 228.095 | 39.729 |
| 98.409 | 231.428 | 39.775 |
| 83.039 | 237.355 | 39.884 |
| 182.202 | 184.935 | 45.998 |
| 169.736 | 196.423 | 46.001 |
| 153.144 | 209.591 | 46.030 |
| 146.216 | 214.470 | 46.050 |
| 131.898 | 223.536 | 46.103 |
| 124.523 | 227.714 | 46.138 |
| 109.375 | 235.340 | 46.222 |
| 185.063 | 187.838 | 49.375 |
| 172.405 | 199.502 | 49.378 |
| 155.557 | 212.869 | 49.405 |
| 148.522 | 217.821 | 49.423 |
| 133.983 | 227.022 | 49.474 |
| 126.494 | 231.262 | 49.506 |
| 139.296 | 235.862 | 58.265 |
| 194.459 | 197.371 | 60.841 |
| 181.184 | 209.612 | 60.848 |
| 163.518 | 223.648 | 60.886 |
| 156.141 | 228.850 | 60.911 |
| 161.667 | 236.846 | 69.607 |
| 203.483 | 206.524 | 72.398 |
| 189.612 | 219.316 | 72.405 |
| 171.152 | 233.983 | 72.444 |
| 210.278 | 213.418 | 81.456 |

TABLE 2

| ρ | z |
|---|---|
| 0.000 | 78.022 |
| 0.085 | 78.013 |
| 0.255 | 78.005 |
| 0.388 | 77.999 |
| 0.475 | 77.996 |
| 0.647 | 77.988 |
| 0.816 | 77.981 |
| 0.981 | 77.975 |
| 1.142 | 77.968 |
| 1.300 | 77.962 |
| 1.454 | 77.955 |
| 1.605 | 77.949 |
| 1.753 | 77.943 |
| 1.896 | 77.938 |
| 2.037 | 77.932 |
| 2.173 | 77.927 |
| 2.372 | 77.920 |
| 2.563 | 77.913 |
| 2.746 | 77.907 |
| 2.921 | 77.901 |
| 3.088 | 77.895 |
| 3.399 | 77.886 |
| 3.589 | 77.881 |
| 3.808 | 77.875 |
| 4.005 | 77.870 |
| 4.182 | 77.867 |
| 4.380 | 77.864 |
| 4.576 | 77.862 |
| 4.762 | 77.861 |
| 4.937 | 77.862 |
| 5.109 | 77.864 |
| 5.278 | 77.866 |
| 5.443 | 77.867 |
| 5.604 | 77.869 |
| 5.762 | 77.871 |
| 5.917 | 77.873 |
| 6.215 | 77.877 |
| 6.499 | 77.882 |
| 6.736 | 77.886 |
| 6.994 | 77.891 |
| 7.238 | 77.896 |
| 7.440 | 77.900 |
| 7.685 | 77.906 |
| 7.937 | 77.913 |
| 8.167 | 77.920 |
| 8.396 | 77.928 |
| 8.565 | 77.935 |
| 8.866 | 77.947 |
| 9.106 | 77.959 |
| 9.348 | 77.974 |
| 9.481 | 77.984 |
| 9.695 | 77.999 |
| 9.903 | 78.014 |
| 10.107 | 78.029 |
| 10.304 | 78.044 |
| 10.496 | 78.059 |
| 10.683 | 78.073 |
| 10.865 | 78.087 |
| 11.041 | 78.102 |
| 11.211 | 78.116 |
| 11.568 | 78.146 |
| 11.722 | 78.159 |
| 11.899 | 78.175 |
| 12.069 | 78.190 |
| 12.231 | 78.205 |
| 12.386 | 78.220 |
| 12.557 | 78.236 |
| 12.719 | 78.252 |
| 12.890 | 78.270 |
| 13.050 | 78.287 |
| 13.213 | 78.304 |
| 13.406 | 78.326 |
| 13.608 | 78.350 |
| 13.803 | 78.374 |
| 13.963 | 78.396 |
| 14.141 | 78.421 |
| 14.316 | 78.446 |
| 14.487 | 78.470 |
| 14.655 | 78.494 |
| 14.819 | 78.518 |
| 14.980 | 78.542 |
| 15.138 | 78.565 |
| 15.292 | 78.588 |
| 15.443 | 78.611 |
| 15.591 | 78.633 |
| 15.735 | 78.656 |
| 15.876 | 78.677 |
| 16.014 | 78.699 |
| 16.181 | 78.725 |
| 16.344 | 78.751 |
| 16.501 | 78.777 |
| 16.653 | 78.801 |
| 16.800 | 78.826 |
| 16.942 | 78.849 |
| 17.079 | 78.872 |
| 17.211 | 78.895 |
| 17.363 | 78.921 |
| 17.508 | 78.947 |
| 17.645 | 78.971 |
| 17.797 | 78.998 |
| 17.940 | 79.024 |
| 18.091 | 79.053 |
| 18.327 | 79.098 |
| 18.648 | 79.161 |
| 18.951 | 79.225 |
| 19.229 | 79.286 |
| 19.499 | 79.345 |
| 19.762 | 79.403 |
| 20.307 | 79.526 |
| 20.547 | 79.581 |
| 20.780 | 79.635 |
| 20.969 | 79.679 |
| 21.153 | 79.722 |
| 21.367 | 79.773 |
| 21.574 | 79.823 |
| 21.806 | 79.879 |
| 21.998 | 79.926 |
| 22.183 | 79.972 |
| 22.361 | 80.016 |
| 22.533 | 80.059 |
| 22.751 | 80.115 |
| 22.907 | 80.155 |
| 23.080 | 80.200 |
| 23.245 | 80.243 |
| 23.401 | 80.285 |
| 23.647 | 80.352 |
| 23.903 | 80.422 |
| 24.034 | 80.459 |
| 24.251 | 80.521 |
| 24.363 | 80.553 |
| 24.573 | 80.615 |
| 24.725 | 80.660 |
| 24.875 | 80.705 |
| 25.023 | 80.750 |
| 25.170 | 80.794 |
| 25.314 | 80.837 |
| 25.457 | 80.881 |
| 25.599 | 80.924 |
| 25.739 | 80.967 |
| 25.876 | 81.009 |
| 26.013 | 81.051 |
| 26.147 | 81.093 |
| 26.280 | 81.134 |
| 26.411 | 81.175 |
| 26.541 | 81.215 |
| 26.669 | 81.255 |
| 26.795 | 81.295 |
| 26.919 | 81.334 |
| 27.042 | 81.373 |
| 27.164 | 81.412 |
| 27.283 | 81.450 |
| 27.401 | 81.488 |
| 27.517 | 81.526 |
| 27.632 | 81.563 |
| 27.857 | 81.636 |
| 28.075 | 81.707 |
| 28.287 | 81.777 |
| 28.492 | 81.845 |
| 28.691 | 81.912 |
| 28.884 | 81.977 |
| 29.071 | 82.041 |
| 29.252 | 82.103 |
| 29.426 | 82.163 |
| 29.595 | 82.221 |
| 29.758 | 82.278 |
| 29.914 | 82.333 |
| 30.065 | 82.387 |
| 30.210 | 82.439 |
| 30.349 | 82.489 |
| 30.483 | 82.537 |
| 30.610 | 82.583 |
| 30.733 | 82.628 |
| 30.849 | 82.671 |
| 30.960 | 82.713 |
| 31.066 | 82.752 |
| 31.174 | 82.793 |
| 31.349 | 82.859 |
| 31.464 | 82.902 |
| 31.579 | 82.946 |
| 31.749 | 83.011 |
| 31.862 | 83.054 |
| 31.974 | 83.096 |
| 32.086 | 83.139 |
| 32.197 | 83.182 |
| 32.471 | 83.287 |
| 32.687 | 83.370 |
| 32.900 | 83.453 |
| 33.111 | 83.535 |
| 33.318 | 83.616 |
| 33.524 | 83.697 |
| 33.876 | 83.836 |
| 34.074 | 83.914 |
| 34.269 | 83.992 |
| 34.462 | 84.069 |
| 34.651 | 84.145 |
| 34.839 | 84.221 |
| 34.978 | 84.277 |
| 35.206 | 84.369 |
| 35.385 | 84.442 |
| 35.562 | 84.515 |
| 35.737 | 84.586 |
| 35.909 | 84.657 |
| 36.078 | 84.727 |
| 36.245 | 84.796 |
| 36.410 | 84.865 |
| 36.572 | 84.933 |
| 36.731 | 85.000 |
| 36.888 | 85.066 |
| 37.043 | 85.131 |
| 37.195 | 85.196 |
| 37.345 | 85.259 |
| 37.493 | 85.322 |
| 37.638 | 85.385 |
| 37.781 | 85.446 |
| 37.990 | 85.537 |
| 38.195 | 85.625 |
| 38.394 | 85.712 |
| 38.588 | 85.798 |
| 38.778 | 85.881 |
| 38.962 | 85.962 |
| 39.141 | 86.042 |
| 39.315 | 86.120 |
| 39.484 | 86.196 |
| 39.637 | 86.265 |
| 39.778 | 86.329 |
| 39.919 | 86.393 |
| 40.060 | 86.457 |
| 40.199 | 86.520 |
| 40.338 | 86.584 |
| 40.477 | 86.647 |
| 40.615 | 86.710 |
| 40.752 | 86.773 |
| 40.889 | 86.835 |
| 41.025 | 86.898 |
| 41.161 | 86.960 |
| 41.296 | 87.022 |
| 41.430 | 87.084 |
| 41.564 | 87.146 |
| 41.697 | 87.207 |
| 41.830 | 87.269 |
| 41.962 | 87.330 |
| 42.093 | 87.391 |
| 42.289 | 87.482 |
| 42.484 | 87.573 |
| 42.678 | 87.663 |
| 42.870 | 87.753 |
| 43.061 | 87.843 |
| 43.251 | 87.932 |
| 43.439 | 88.021 |
| 43.626 | 88.109 |
| 43.812 | 88.197 |
| 43.997 | 88.285 |
| 44.181 | 88.372 |
| 44.363 | 88.459 |
| 44.544 | 88.545 |
| 44.724 | 88.631 |
| 44.903 | 88.717 |
| 45.080 | 88.802 |
| 45.256 | 88.887 |
| 45.432 | 88.971 |
| 45.605 | 89.055 |
| 45.778 | 89.138 |
| 45.950 | 89.222 |
| 46.120 | 89.304 |
| 46.289 | 89.387 |
| 46.457 | 89.469 |
| 46.624 | 89.550 |
| 46.790 | 89.631 |
| 46.955 | 89.712 |
| 47.118 | 89.793 |
| 47.280 | 89.873 |
| 47.442 | 89.952 |
| 47.602 | 90.031 |
| 47.761 | 90.110 |
| 47.919 | 90.188 |
| 48.075 | 90.266 |
| 48.231 | 90.344 |
| 48.386 | 90.421 |
| 48.539 | 90.498 |
| 48.691 | 90.574 |
| 48.843 | 90.650 |
| 48.993 | 90.726 |
| 49.142 | 90.801 |
| 49.290 | 90.875 |
| 49.437 | 90.950 |
| 49.583 | 91.024 |
| 49.728 | 91.097 |
| 49.872 | 91.170 |
| 50.015 | 91.243 |
| 50.157 | 91.316 |
| 50.344 | 91.411 |
| 50.483 | 91.483 |
| 50.622 | 91.554 |
| 50.759 | 91.624 |
| 50.895 | 91.695 |
| 51.122 | 91.812 |
| 51.306 | 91.907 |
| 51.490 | 92.002 |
| 51.673 | 92.097 |
| 51.947 | 92.239 |
| 52.128 | 92.333 |
| 52.310 | 92.428 |
| 52.491 | 92.522 |
| 52.671 | 92.616 |
| 52.852 | 92.710 |
| 53.031 | 92.804 |
| 53.210 | 92.897 |
| 53.389 | 92.991 |
| 53.568 | 93.084 |
| 53.746 | 93.178 |
| 53.923 | 93.271 |
| 54.100 | 93.364 |
| 54.277 | 93.457 |
| 54.453 | 93.549 |
| 54.629 | 93.642 |
| 54.804 | 93.734 |
| 54.979 | 93.827 |
| 55.154 | 93.919 |
| 55.328 | 94.011 |
| 55.502 | 94.103 |
| 55.675 | 94.195 |
| 55.848 | 94.287 |
| 56.020 | 94.378 |
| 56.193 | 94.470 |
| 56.364 | 94.561 |
| 56.536 | 94.652 |
| 56.707 | 94.743 |
| 56.877 | 94.834 |
| 57.047 | 94.925 |
| 57.217 | 95.016 |
| 57.386 | 95.106 |
| 57.555 | 95.197 |
| 57.724 | 95.287 |
| 58.060 | 95.468 |
| 58.228 | 95.558 |
| 58.395 | 95.647 |
| 58.561 | 95.737 |
| 58.728 | 95.827 |
| 58.894 | 95.916 |
| 59.059 | 96.006 |
| 59.225 | 96.095 |
| 59.389 | 96.184 |
| 59.554 | 96.273 |
| 59.718 | 96.362 |
| 59.882 | 96.451 |
| 60.045 | 96.540 |
| 60.208 | 96.628 |
| 60.371 | 96.717 |
| 60.533 | 96.805 |
| 60.695 | 96.893 |
| 60.857 | 96.981 |
| 61.018 | 97.069 |
| 61.179 | 97.157 |
| 61.340 | 97.245 |
| 61.500 | 97.333 |
| 61.660 | 97.420 |
| 61.820 | 97.508 |
| 61.979 | 97.595 |
| 62.138 | 97.682 |
| 62.297 | 97.769 |
| 62.455 | 97.856 |
| 62.613 | 97.943 |
| 62.771 | 98.030 |
| 62.928 | 98.117 |
| 63.085 | 98.203 |
| 63.241 | 98.290 |
| 63.398 | 98.376 |
| 63.554 | 98.462 |
| 63.709 | 98.549 |
| 63.865 | 98.635 |
| 64.020 | 98.721 |
| 64.174 | 98.806 |
| 64.329 | 98.892 |
| 64.483 | 98.978 |
| 64.636 | 99.063 |
| 64.790 | 99.149 |
| 64.943 | 99.234 |
| 65.096 | 99.319 |
| 65.248 | 99.404 |
| 65.401 | 99.489 |
| 65.552 | 99.574 |
| 65.704 | 99.659 |
| 65.855 | 99.744 |
| 66.006 | 99.828 |
| 66.157 | 99.913 |
| 66.307 | 99.997 |
| 66.458 | 100.081 |
| 66.607 | 100.165 |
| 66.757 | 100.250 |
| 66.906 | 100.333 |
| 67.055 | 100.417 |
| 67.204 | 100.501 |
| 67.352 | 100.585 |
| 67.500 | 100.668 |

TABLE 3

| x | y | z |
|---|---|---|
| 0.900 | 15.153 | 16.072 |
| 0.971 | 15.042 | 16.990 |
| 1.005 | 14.908 | 17.770 |
| 0.979 | 14.562 | 19.181 |
| 0.924 | 14.353 | 19.822 |
| 0.773 | 13.916 | 20.901 |
| 0.672 | 13.678 | 21.386 |
| 0.543 | 13.412 | 21.864 |
| 0.412 | 13.151 | 22.283 |
| 0.267 | 12.879 | 22.674 |
| 0.110 | 12.597 | 23.037 |
| −0.060 | 12.305 | 23.373 |
| 1.812 | 15.270 | 15.168 |
| 1.983 | 15.100 | 17.054 |
| 1.969 | 14.626 | 19.302 |
| 1.840 | 14.219 | 20.516 |
| 1.754 | 14.001 | 21.044 |
| 1.651 | 13.771 | 21.538 |
| 1.535 | 13.530 | 21.999 |
| 1.391 | 13.260 | 22.457 |
| 1.247 | 12.997 | 22.858 |
| 1.090 | 12.725 | 23.233 |
| 0.922 | 12.443 | 23.583 |
| 0.742 | 12.151 | 23.907 |
| 0.533 | 11.830 | 24.226 |
| 0.330 | 11.520 | 24.502 |
| 0.115 | 11.200 | 24.756 |
| −0.111 | 10.871 | 24.987 |
| 2.788 | 15.254 | 15.172 |
| 2.887 | 15.195 | 16.140 |
| 2.923 | 14.653 | 19.296 |
| 2.592 | 13.819 | 21.613 |
| 2.033 | 12.809 | 23.357 |
| 1.867 | 12.536 | 23.720 |
| 1.689 | 12.254 | 24.058 |
| 1.500 | 11.964 | 24.373 |
| 1.283 | 11.644 | 24.684 |
| 1.188 | 11.502 | 24.812 |
| 1.072 | 11.336 | 24.953 |
| 0.973 | 11.189 | 25.071 |
| 0.851 | 11.019 | 25.200 |
| 0.747 | 10.868 | 25.309 |
| 0.619 | 10.693 | 25.426 |
| 0.510 | 10.538 | 25.525 |
| 0.377 | 10.358 | 25.630 |
| 0.262 | 10.199 | 25.719 |
| 0.123 | 10.014 | 25.813 |
| 0.003 | 9.851 | 25.892 |
| −0.142 | 9.660 | 25.975 |
| 3.763 | 15.160 | 15.533 |
| 3.701 | 14.252 | 20.515 |
| 3.613 | 14.051 | 21.069 |
| 3.500 | 13.825 | 21.620 |
| 3.111 | 13.122 | 22.989 |
| 2.943 | 12.852 | 23.416 |
| 2.416 | 12.036 | 24.473 |
| 1.995 | 11.430 | 25.084 |
| 1.778 | 11.124 | 25.347 |
| 1.675 | 10.979 | 25.463 |
| 1.313 | 10.487 | 25.811 |
| 1.201 | 10.333 | 25.907 |
| 1.065 | 10.155 | 26.012 |
| 0.948 | 9.998 | 26.099 |
| 0.807 | 9.814 | 26.192 |
| 0.685 | 9.653 | 26.270 |
| 0.538 | 9.465 | 26.352 |
| 0.411 | 9.299 | 26.419 |
| 0.126 | 8.935 | 26.548 |
| −0.172 | 8.561 | 26.655 |
| 4.714 | 14.978 | 16.279 |
| 4.756 | 14.771 | 17.988 |
| 4.540 | 14.110 | 20.696 |
| 3.751 | 12.738 | 23.599 |
| 3.302 | 12.070 | 24.514 |
| 3.108 | 11.791 | 24.835 |
| 2.790 | 11.348 | 25.287 |
| 2.572 | 11.049 | 25.556 |
| 2.106 | 10.427 | 26.033 |
| 1.973 | 10.255 | 26.147 |
| 1.721 | 9.926 | 26.345 |
| 1.458 | 9.589 | 26.523 |
| 1.185 | 9.243 | 26.681 |
| 0.901 | 8.888 | 26.819 |
| 0.300 | 8.148 | 27.031 |
| 0.009 | 7.791 | 27.102 |
| 5.515 | 14.839 | 15.487 |
| 5.560 | 14.439 | 18.890 |
| 5.433 | 14.113 | 20.231 |
| 5.122 | 13.525 | 21.921 |
| 4.692 | 12.838 | 23.327 |
| 4.059 | 11.925 | 24.680 |
| 3.970 | 11.798 | 24.834 |
| 3.863 | 11.652 | 25.005 |
| 3.769 | 11.522 | 25.150 |
| 3.656 | 11.371 | 25.309 |
| 3.559 | 11.237 | 25.445 |
| 3.441 | 11.082 | 25.593 |
| 3.321 | 10.925 | 25.737 |
| 3.216 | 10.786 | 25.858 |
| 3.091 | 10.625 | 25.991 |
| 2.983 | 10.482 | 26.102 |
| 2.852 | 10.316 | 26.225 |
| 2.740 | 10.169 | 26.327 |
| 2.487 | 9.849 | 26.533 |
| 2.225 | 9.520 | 26.720 |
| 1.953 | 9.182 | 26.887 |
| 1.672 | 8.836 | 27.034 |
| 1.515 | 8.647 | 27.105 |
| 1.217 | 8.287 | 27.222 |
| 0.908 | 7.916 | 27.318 |
| 0.614 | 7.563 | 27.388 |
| 0.282 | 7.172 | 27.443 |
| −0.063 | 6.770 | 27.473 |
| 6.346 | 14.599 | 15.560 |
| 6.410 | 14.458 | 17.399 |
| 6.216 | 13.900 | 20.295 |
| 6.116 | 13.714 | 20.922 |
| 6.010 | 13.527 | 21.473 |
| 5.821 | 13.219 | 22.258 |
| 5.671 | 12.992 | 22.764 |
| 5.522 | 12.768 | 23.211 |
| 5.362 | 12.535 | 23.632 |
| 5.192 | 12.294 | 24.030 |
| 5.096 | 12.162 | 24.233 |
| 4.997 | 12.028 | 24.429 |
| 4.911 | 11.908 | 24.596 |
| 4.498 | 11.358 | 25.279 |
| 4.285 | 11.080 | 25.578 |
| 4.063 | 10.794 | 25.858 |
| 3.833 | 10.500 | 26.118 |
| 3.345 | 9.890 | 26.581 |
| 3.088 | 9.573 | 26.785 |
| 2.822 | 9.247 | 26.969 |
| 2.260 | 8.571 | 27.281 |
| 1.965 | 8.220 | 27.409 |
| 1.659 | 7.859 | 27.516 |
| 1.342 | 7.488 | 27.602 |
| 1.013 | 7.107 | 27.668 |
| 0.672 | 6.715 | 27.712 |
| 0.348 | 6.341 | 27.732 |
| −0.019 | 5.925 | 27.730 |
| −0.223 | 5.697 | 27.718 |
| 7.164 | 14.294 | 16.059 |
| 7.187 | 14.230 | 16.950 |
| 7.164 | 14.078 | 18.228 |
| 7.143 | 14.016 | 18.621 |
| 7.121 | 13.957 | 18.954 |
| 7.089 | 13.885 | 19.320 |
| 7.052 | 13.809 | 19.673 |
| 7.010 | 13.728 | 20.015 |
| 6.971 | 13.654 | 20.305 |
| 6.921 | 13.567 | 20.626 |
| 6.867 | 13.475 | 20.936 |
| 6.757 | 13.295 | 21.492 |
| 6.487 | 12.888 | 22.543 |
| 6.328 | 12.661 | 23.039 |
| 6.002 | 12.208 | 23.892 |
| 5.824 | 11.969 | 24.282 |
| 5.425 | 11.449 | 25.021 |
| 5.006 | 10.915 | 25.652 |
| 4.783 | 10.636 | 25.938 |
| 4.293 | 10.035 | 26.470 |
| 3.786 | 9.423 | 26.908 |
| 3.243 | 8.778 | 27.273 |
| 2.958 | 8.444 | 27.427 |
| 2.824 | 8.285 | 27.492 |
| 2.664 | 8.100 | 27.562 |
| 2.524 | 7.938 | 27.619 |
| 2.359 | 7.748 | 27.679 |
| 2.215 | 7.581 | 27.726 |
| 2.044 | 7.386 | 27.775 |
| 1.895 | 7.215 | 27.813 |
| 1.744 | 7.041 | 27.847 |
| 1.564 | 6.838 | 27.880 |
| 1.408 | 6.660 | 27.904 |
| 1.221 | 6.450 | 27.925 |
| 1.059 | 6.267 | 27.939 |
| 0.895 | 6.081 | 27.947 |
| 0.698 | 5.862 | 27.950 |
| 0.527 | 5.671 | 27.948 |
| 0.322 | 5.445 | 27.937 |
| 0.145 | 5.247 | 27.923 |
| −0.036 | 5.046 | 27.903 |
| 7.892 | 13.989 | 15.461 |
| 7.932 | 13.878 | 17.322 |
| 7.852 | 13.656 | 18.943 |
| 7.693 | 13.367 | 20.302 |
| 7.469 | 13.021 | 21.499 |
| 7.342 | 12.835 | 22.027 |
| 7.203 | 12.639 | 22.527 |
| 7.041 | 12.420 | 23.029 |
| 6.881 | 12.205 | 23.474 |
| 6.697 | 11.966 | 23.921 |
| 6.516 | 11.734 | 24.317 |
| 6.326 | 11.493 | 24.691 |
| 6.128 | 11.244 | 25.043 |
| 5.905 | 10.970 | 25.397 |
| 5.689 | 10.705 | 25.708 |
| 5.464 | 10.433 | 26.000 |
| 5.231 | 10.153 | 26.273 |
| 5.103 | 10.001 | 26.411 |
| 4.990 | 9.866 | 26.527 |
| 4.857 | 9.710 | 26.655 |
| 4.741 | 9.571 | 26.763 |
| 4.603 | 9.411 | 26.881 |
| 4.483 | 9.269 | 26.980 |
| 4.340 | 9.104 | 27.089 |
| 4.216 | 8.959 | 27.180 |
| 4.069 | 8.789 | 27.279 |
| 3.941 | 8.640 | 27.362 |
| 3.789 | 8.467 | 27.451 |
| 3.657 | 8.314 | 27.525 |
| 3.500 | 8.136 | 27.605 |
| 3.364 | 7.979 | 27.670 |
| 3.202 | 7.796 | 27.739 |
| 3.061 | 7.636 | 27.796 |
| 2.894 | 7.448 | 27.855 |
| 2.748 | 7.283 | 27.903 |
| 2.575 | 7.090 | 27.952 |
| 2.425 | 6.921 | 27.990 |
| 2.091 | 6.548 | 28.058 |
| 1.746 | 6.165 | 28.104 |
| 1.417 | 5.800 | 28.127 |
| 1.048 | 5.394 | 28.130 |
| 0.664 | 4.975 | 28.108 |
| 0.265 | 4.542 | 28.060 |
| −0.116 | 4.128 | 27.991 |
| 8.633 | 13.611 | 15.815 |
| 8.591 | 13.389 | 18.441 |
| 8.343 | 12.979 | 20.535 |
| 8.233 | 12.819 | 21.122 |
| 8.100 | 12.636 | 21.711 |
| 7.963 | 12.452 | 22.232 |
| 7.816 | 12.259 | 22.724 |
| 7.647 | 12.042 | 23.220 |
| 7.478 | 11.830 | 23.659 |
| 7.384 | 11.713 | 23.883 |
| 7.287 | 11.594 | 24.101 |
| 7.201 | 11.487 | 24.286 |
| 7.100 | 11.364 | 24.492 |
| 7.010 | 11.254 | 24.667 |
| 6.904 | 11.126 | 24.862 |
| 6.795 | 10.996 | 25.050 |
| 6.699 | 10.880 | 25.210 |
| 6.143 | 10.224 | 26.005 |
| 6.018 | 10.079 | 26.157 |
| 5.780 | 9.803 | 26.428 |
| 5.649 | 9.652 | 26.565 |
| 5.534 | 9.519 | 26.680 |
| 5.139 | 9.069 | 27.032 |
| 4.313 | 8.136 | 27.597 |
| 3.881 | 7.654 | 27.815 |
| 2.933 | 6.607 | 28.135 |
| 2.437 | 6.064 | 28.228 |
| 1.916 | 5.499 | 28.275 |
| 1.545 | 5.097 | 28.279 |
| 1.160 | 4.683 | 28.259 |
| 0.760 | 4.255 | 28.214 |
| 0.377 | 3.845 | 28.147 |
| −0.134 | 3.307 | 28.024 |
| 9.329 | 13.195 | 16.088 |
| 9.328 | 13.144 | 17.034 |
| 9.299 | 13.071 | 17.850 |
| 9.207 | 12.912 | 19.037 |
| 9.126 | 12.789 | 19.716 |
| 9.021 | 12.643 | 20.395 |
| 8.909 | 12.492 | 20.992 |
| 8.774 | 12.318 | 21.592 |
| 8.636 | 12.143 | 22.122 |
| 8.558 | 12.046 | 22.393 |
| 8.476 | 11.945 | 22.656 |
| 8.316 | 11.750 | 23.129 |
| 8.226 | 11.642 | 23.370 |
| 8.133 | 11.531 | 23.605 |
| 8.051 | 11.432 | 23.805 |
| 7.953 | 11.317 | 24.027 |
| 7.853 | 11.200 | 24.243 |
| 7.764 | 11.095 | 24.426 |
| 7.660 | 10.973 | 24.630 |
| 7.567 | 10.864 | 24.803 |
| 7.346 | 10.610 | 25.183 |
| 7.012 | 10.229 | 25.689 |
| 6.677 | 9.848 | 26.131 |
| 6.307 | 9.433 | 26.550 |
| 5.917 | 9.000 | 26.927 |
| 5.529 | 8.570 | 27.248 |
| 5.103 | 8.101 | 27.543 |
| 4.678 | 7.637 | 27.786 |
| 4.378 | 7.309 | 27.930 |
| 4.067 | 6.974 | 28.055 |
| 3.748 | 6.629 | 28.162 |
| 3.419 | 6.274 | 28.250 |
| 3.079 | 5.910 | 28.318 |
| 2.728 | 5.535 | 28.365 |
| 2.020 | 4.781 | 28.396 |
| 1.633 | 4.371 | 28.378 |
| 1.449 | 4.177 | 28.361 |
| 1.231 | 3.947 | 28.335 |
| 1.041 | 3.746 | 28.306 |
| 0.847 | 3.542 | 28.270 |
| 0.615 | 3.300 | 28.221 |
| 0.335 | 3.009 | 28.151 |
| 0.037 | 2.701 | 28.065 |
| 9.967 | 12.760 | 15.331 |
| 9.863 | 12.522 | 18.814 |
| 9.821 | 12.465 | 19.190 |
| 9.555 | 12.125 | 20.852 |
| 9.127 | 11.616 | 22.512 |
| 8.875 | 11.325 | 23.242 |
| 8.600 | 11.013 | 23.912 |
| 8.304 | 10.682 | 24.529 |
| 7.989 | 10.331 | 25.096 |
| 7.300 | 9.575 | 26.089 |
| 6.946 | 9.189 | 26.500 |
| 6.556 | 8.767 | 26.890 |
| 6.148 | 8.328 | 27.238 |
| 5.742 | 7.893 | 27.531 |
| 5.296 | 7.418 | 27.799 |
| 4.854 | 6.947 | 28.015 |
| 4.540 | 6.614 | 28.140 |
| 4.217 | 6.273 | 28.247 |
| 3.884 | 5.923 | 28.335 |
| 3.727 | 5.757 | 28.369 |
| 3.541 | 5.562 | 28.403 |
| 3.379 | 5.391 | 28.428 |
| 3.187 | 5.191 | 28.451 |
| 3.020 | 5.015 | 28.466 |
| 2.850 | 4.838 | 28.477 |
| 2.649 | 4.628 | 28.483 |
| 2.474 | 4.445 | 28.483 |
| 2.266 | 4.228 | 28.477 |
| 2.084 | 4.039 | 28.466 |
| 1.680 | 3.619 | 28.424 |
| 1.489 | 3.420 | 28.396 |
| 1.294 | 3.218 | 28.362 |
| 1.062 | 2.978 | 28.314 |
| 0.781 | 2.690 | 28.245 |
| 0.483 | 2.385 | 28.161 |
| 0.134 | 2.028 | 28.047 |
| 10.606 | 12.270 | 15.924 |
| 10.528 | 12.142 | 18.131 |
| 10.249 | 11.807 | 20.296 |
| 9.829 | 11.337 | 22.084 |
| 9.583 | 11.067 | 22.850 |
| 9.022 | 10.462 | 24.203 |
| 8.381 | 9.779 | 25.347 |
| 7.923 | 9.294 | 25.991 |
| 7.682 | 9.040 | 26.285 |
| 7.434 | 8.779 | 26.561 |
| 7.159 | 8.491 | 26.836 |
| 6.895 | 8.214 | 27.075 |
| 6.623 | 7.930 | 27.296 |
| 6.343 | 7.638 | 27.500 |
| 6.055 | 7.338 | 27.686 |
| 5.918 | 7.197 | 27.767 |
| 5.454 | 6.715 | 28.007 |
| 4.487 | 5.714 | 28.352 |
| 3.983 | 5.196 | 28.459 |
| 3.458 | 4.655 | 28.523 |
| 2.907 | 4.089 | 28.541 |
| 2.329 | 3.497 | 28.509 |
| 1.720 | 2.874 | 28.422 |
| 0.907 | 2.047 | 28.225 |
| 11.096 | 11.633 | 18.186 |
| 11.012 | 11.543 | 18.970 |
| 10.908 | 11.433 | 19.700 |
| 10.794 | 11.314 | 20.342 |
| 10.658 | 11.172 | 20.985 |
| 10.518 | 11.026 | 21.553 |
| 10.355 | 10.858 | 22.124 |
| 10.192 | 10.689 | 22.630 |
| 9.524 | 10.004 | 24.238 |
| 9.205 | 9.678 | 24.833 |
| 8.867 | 9.333 | 25.380 |
| 8.511 | 8.970 | 25.880 |
| 8.154 | 8.607 | 26.316 |
| 8.020 | 8.470 | 26.465 |
| 7.622 | 8.066 | 26.866 |
| 7.226 | 7.664 | 27.209 |
| 6.793 | 7.225 | 27.529 |
| 6.363 | 6.789 | 27.795 |
| 5.893 | 6.313 | 28.035 |
| 5.747 | 6.165 | 28.099 |
| 5.576 | 5.992 | 28.168 |
| 5.426 | 5.841 | 28.224 |
| 5.250 | 5.663 | 28.284 |
| 5.096 | 5.507 | 28.331 |
| 4.915 | 5.324 | 28.380 |
| 4.241 | 4.643 | 28.512 |
| 3.703 | 4.100 | 28.562 |
| 3.499 | 3.894 | 28.569 |
| 3.321 | 3.715 | 28.569 |
| 3.110 | 3.502 | 28.564 |
| 2.925 | 3.316 | 28.554 |
| 2.322 | 2.708 | 28.485 |
| 1.608 | 1.989 | 28.339 |
| 1.308 | 1.688 | 28.256 |
| 0.957 | 1.336 | 28.144 |
| 0.593 | 0.970 | 28.011 |
| 0.259 | 0.635 | 27.873 |

### REFERENCES

[1] W. Cassarly, “Nonimaging Optics: Concentration and illumination”, in the Handbook of Optics, 2nd ed., pp. 2.23-2.42, (McGraw-Hill, New York, 2001)
[2]H. Ries, J. M. Gordon, M. Laxen, “High-flux photovoltaic solar concentrators with Kaleidoscope based optical designs”, Solar Energy, Vol. 60, No. 1, pp. 11-16, (1997)
[3] J. J. O'Ghallagher, R. Winston, “Nonimaging solar concentrator with near-uniform irradiance for photovoltaic arrays” in Nonimaging Optics: Maximum Efficiency Light Transfer VI, Roland Winston, Ed., Proc. SPIE 4446, pp. 60-64, (2001)
[4] D. G. Jenkings, “High-uniformity solar concentrators for photovoltaic systems” in Nonimaging Optics Maximum Efficiency Light Transfer VI, Roland Winston, Ed., Proc. SPIE 4446, pp. 52-59, (2001)
[5] http://www.daido.co.jp/english/rd/7503.pdf
[6] http://www.solfocus.com/, also U.S. 2006/0207650, 2006/0274439
[7] www.sol3g.com
[8] L. W. James, “Use of imaging refractive secondaries in photovoltaic concentrators”, SAND 89-7029, Albuquerque, N. Mex., (1989)
[9] Chapter 13, “Next Generation Photovoltaics”, (Taylor & Francis, CRC Press, 2003)
[10] R. Winston, J. C. Miñano, P. Benítez, “Nonimaging Optics”, (Elsevier-Academic Press, New York, 2005)
[11] J. C. Miñano, P. Benítez, J. C. González, “RX: a nonimaging concentrator”, Appl. Opt. 34, pp. 2226-2235, (1995)
[12] P. Benítez, J. C. Miñano, “Ultrahigh-numerical-aperture imaging concentrator”, J. Opt. Soc. Am. A, 14, pp. 1988-1997, (1997)
[13] J. C. Miñano, M. Hernandez, P. Benítez, J. Blen, O. Dross, R. Mohedano, A. Santamaria, “Free-form integrator array optics”, in Nonimaging Optics and Efficient Illumination Systems II, SPIE Proc., R. Winston & T. J. Koshel ed. (2005)
[14] US and other patents and patent applications: U.S. Pat. No. 6,639,733; U.S. Pat. No. 6,896,381; U.S. Pat. No. 7,152,985; U.S. Pat. No. 7,460,985; WO 2007/016363; US 2009/0071467; US 2008/0223443; US 2008/0316761.
[15] P. Benítez, A. Cvetkovic, R. Winston, G. Diaz, L. Reed, J. Cisneros, A. Tovar, A. Ritschel, J. Wright, “High-Concentration Mirror-Based Köhler Integrating System for Tandem Solar Cells”, 4th World Conference on Photovoltaic Energy Conversion, Hawaii, (2006).
[16] J. Chaves, “Introduction to Nonimaging Optics”, CRC Press, 2008, Chapter 17.

What is claimed is:

1. An optical device comprising a primary optical element, an intermediate optical element, and a secondary optical element, wherein:
each of the primary and secondary optical elements comprises a plurality of sections;
each section of the primary optical element and a respective section of the secondary optical element form a Köhler integrator arranged to transmit light from a source common to the lenticulations to a target common to the sections; and
light passing between the primary and secondary optical elements is deflected by the intermediate optical element.

2. The optical device of claim 1, wherein the primary and intermediate optical elements are reflective and the secondary optical element is refractive.

3. The optical device of claim 1, wherein the primary and secondary optical elements are reflective and the intermediate optical element is refractive.

4. The optical device of claim 1, wherein the intermediate optical element comprises a single smooth optical surface common to the sections.

5. The optical device of claim 1, wherein the primary and secondary optical elements are free-form and the intermediate optical element is rotationally symmetric.

6. The optical device of claim 1, wherein the Köhler integrators are operative to integrate light in both sagittal and meridional directions.

8. The optical device of claim 1, which is a solar concentrator, and wherein the target is a photovoltaic device attached to the secondary optical element.

9. The optical device of claim 1, wherein the segments of the primary optical element are so arranged as to produce substantially coincident images of their respective segments of the secondary optical element at the common source, and wherein the segments of the secondary optical element are so arranged as to produce substantially coincident images of their respective segments of the primary optical element at the common target.

10. The optical device of claim 1, wherein at least one of the primary and secondary optical elements is operative to concentrate or collimate light reaching that element from the common source or being directed by that element onto the common target.

11. The optical element of claim 1, wherein the primary and secondary optical elements each comprise sections symmetrically arranged around a common axis and displaced from each other in rotation about the common axis.

12. The optical device of claim 1, further comprising a central axis, wherein the common target further comprises a device for converting light into another form of energy, and wherein each of the plurality of Köhler integrators is arranged to direct collimated light incident parallel to said central axis over the common target.

13. The optical device of claim 12, wherein the device for converting energy is a photovoltaic cell.

14. The optical device of claim 1, wherein the secondary optical element is a dielectric element having the plurality of segments formed in one surface and having the common source or common target at another surface.

15. An optical device comprising a primary optical element and a secondary optical element, wherein:
each of the primary and secondary optical elements comprises a plurality of sections;
each section of the primary optical element and a respective section of the secondary optical element form a Köhler integrator arranged to transmit light from a source common to the sections to a target common to the sections; and
the secondary optical element is outside the beam of light from the source to the primary optical element that is deflected by the primary optical element to the secondary optical element.

16. The optical device of claim 13, wherein the primary and secondary optical elements are free-form.

17. The optical device of claim 15, which is a solar concentrator, and wherein the target is a photovoltaic device attached to the secondary optical element.

18. The optical device of claim 15, wherein the secondary optical element is a refractive surface on a dielectric element that extends from the refractive surface to the target.

19. The optical device of claim 15, wherein the secondary optical element is a reflective rear surface on a dielectric element that extends from the reflective surface to the target.

20. The optical device of claim 15, comprising a plurality of said primary optical elements and a corresponding plurality of secondary optical element, wherein each secondary element is separated from its associated primary optical element by another primary optical element.
